(19) United States
(12) Patent Application Publication
(10) Pub. No.: US 2018/0215894 A1
(43) Pub. Date: Aug. 2, 2018

(54) MATERIALS EXHIBITING IMPROVED METAL BONDING STRENGTH VIA ADDITION OF PHOTOPERMEABLE COLORANT

(71) Applicant: SABIC Global Technologies B.V., Bergen op Zoom (NL)

(72) Inventors: Yunan CHENG, Shanghai (CN); Yun ZHENG, Shanghai (CN); Huihui LI, Shanghai (CN); Haowei TANG, Shanghai (CN); Chao LIU, Shanghai (CN); Richard LIU, Shenzhen (CN)

(21) Appl. No.: 15/746,985

(22) PCT Filed: Jul. 29, 2016
(86) PCT No.: PCT/IB2016/054590

§ 371 Date: Jan. 23, 2018

Related U.S. Application Data
(60) Provisional application No. 62/199,091, filed on Jul. 30, 2015.

(51) Int. Cl. C08K 3/22; C08K 3/013; C08K 5/00; C08K 7/14; C08K 7/06; C08L 69/00

(52) U.S. Cl. CPC C08K 3/22; C08K 3/013; C08K 5/0041; H05K 1/0373; C08K 7/06; C08L 69/005; C08K 7/14

(57) ABSTRACT

The disclosure concerns polymer compositions exhibiting LDS properties while maintaining mechanical properties and a dark color throughout the composition.

### CROSS REFERENCE TO RELATED APPLICATIONS

The present application claims priority to and the benefit of U.S. application 62/199,091, “Materials Exhibiting Improved Metal Bonding Strength Via Addition of Photopermeable Colorant” (filed, Jul. 30, 2015) the entirety of which is incorporated herein by reference for any and all purposes.

### TECHNICAL FIELD

The disclosure concerns laser activatable resin compositions containing photopermeable pigments.

### BACKGROUND

Laser activable or laser platable materials are increasing useful in industrial applications. These materials employ laser irradiation to deliver the material certain properties. When exposed to laser irradiation, a material, containing a laser platable additive will have its metal atoms activated. These activated metal ions are raised to the material surface in the areas exposed to the laser irradiation. The laser platable additive can be selected so that, after a given material is subjected to laser irradiation, the exposed or “etching” area is capable of being plated to form a conductive structure. The laser-etched area creates a conductive path allowing for metallalization, useful in the production of antennae, circuitry, and the like. Such laser platable processes thus allow for sophisticated systems combining mechanical and electrical properties for a variety of applications including, automotive, electronic, and medical.

### SUMMARY

Laser platable processes, such as for example, laser direct structuring processes, can provide a means of delivering a metallic pattern onto electrically insulated plastic surfaces. The addition of a laser direct structuring additive can enable metallization of certain areas of three-dimensional plastic surfaces by selective activation followed by selective metal deposition through a chemical plating process. Given their conductive metallic properties, the materials are apt for use in electronic appliances where variety in color may be desirable. As such, laser direct structuring materials or compositions can often contain carbon black as a pigment to deliver a dark or black color to the composition. Carbon black pigment however also absorbs infrared wavelengths which can heat and remove the surface resin thereby damaging the surface of the composition and hindering laser platability, or metal bonding ability. It would be beneficial to provide a laser activatable composition that can attain a black or dark color without impaired metal plating ability.

The present disclosure relates to compositions comprising a polymer base resin, a laser direct structuring additive, a reinforcing filler, and a photopermeable colorant.

The present disclosure further relates to compositions comprising a polymer base resin and a photopermeable colorant wherein the composition is black or contains sufficient pigment to establish a dark color throughout the composition by and wherein the composition is capable of metal activation to achieve a conductive path suitable for metal bonding or plating at laser irradiated areas of the composition. The compositions can comprise from about 10 weight percent (wt. %) to about 90 wt. % of a polymer base resin; from about 0.1 wt. % to about 60 wt. % of a reinforcing filler; from about 0.1 wt. % to about 10 wt. % of a laser direct structuring additive; and from about 0.01 wt. % to about 10 wt. % of a photopermeable colorant, wherein the combined weight percent value of all components does not exceed about 100 wt. %, wherein all weight percent values are based on the total weight of the composition, wherein the composition exhibits a percent transmittance of up to about 20% at from about 190 nanometers (nm) to about 400 nm and a percent transmittance of greater than 50% at from about 700 nm to about 2500 nm, wherein the composition is configured to be metal plated, and wherein the metal plated composition exhibits an average Plating Index at less than 10% difference from a Plating Index of a substantially similar metal plated composition in the absence of a photopermeable colorant when tested at the same laser intensities.

A composition comprising: from 10 wt. % to 90 wt. % of a polymer base resin; from 0.1 wt. % to 60 wt. % of a reinforcing filler; from 0.1 wt. % to 10 wt. % of a laser direct structuring additive; and from 0.01 wt. % to 10 wt. % of a photopermeable colorant, wherein the combined weight percent value of all components does not exceed 100 wt. %, and wherein all weight percent values are based on the total weight of the composition, wherein the composition exhibits a change in transmittance of at least 20% between a transmittance observed between 190 nm and 400 nm and a transmittance observed from 700 nm to 2500 nm; and wherein the composition is configured to be activated by laser.

Furthermore, the present disclosure relates to a method of forming a composition comprising combining a polymer base substrate, a laser direct structuring additive, a reinforcing filler, and a photopermeable colorant.

The disclosure relates to a method of forming a photopermeable, laser platable article comprising the steps of molding an article from the composition described herein.

### BRIEF DESCRIPTION OF THE FIGURES

FIG. 1 shows transmittance of colorants from 200 nm to 2500 nm.

FIG. 2 shows a graphical illustration of the LDS test parameters: plating index, peel strength, and cross hatch.

FIG. 3 shows percent transmittance of control and example compositions from 200 nm to 2500 nm.

FIG. 4 shows a comparison of mechanical properties between an LDS composition containing carbon black and an LDS composition containing an alternative additive

FIG. 5 shows the cross hatch performance of control and sample compositions.

FIG. 6 shows a comparison of mechanical properties between a natural sample and an LDS composition containing carbon black.

FIG. 7 shows a comparison of mechanical properties between a natural sample and an LDS composition containing an alternative photopermeable additive.

FIG. 8 shows transmittance of nature sample compared to control samples at wavelengths from 200 nm to 2500 nm.

FIG. 9 shows transmittance of nature sample compared to examples at wavelengths from 200 nm to 2500 nm.

FIG. 10 shows transmittance for control samples and examples at colorant concentrations of 0% to 2%.

FIG. 11 shows peel strength at 10 W and 40 kHz at 2 m/s for control samples examples at colorant concentrations between 0% and 2%.

FIG. 12 shows peel strength at 8 W and 40 kHz at 2 m/s for control samples examples at colorant concentrations between 0% and 2%.

FIG. 13 shows peel strength at 5 W and 40 kHz at 2 m/s for control samples examples at colorant concentrations between 0% and 2%.

FIG. 14 shows peel strength at 3 W and 40 kHz at 2 m/s for control samples examples at colorant concentrations between 0% and 2%.

FIG. 15 shows peel strength at 8 W and 100 kHz at 2 m/s for control samples examples at colorant concentrations between 0% and 2%.

FIG. 16 shows peel strength at 5 W and 100 kHz at 2 m/s for control samples examples at colorant concentrations between 0% and 2%.

### DETAILED DESCRIPTION

Laser platable processes, including but not limited to laser direct structuring (LDS) processes, can be employed to selectively deliver metallic and/or conductive properties to the surfaces of materials such as thermoplastic resins. The incorporation of a laser direct structuring additive to a thermoplastic resin, followed by a laser irradiation can be used to achieve metallic conductivity for electronic applications. Often, laser direct structuring materials or compositions can contain carbon black as a pigment to give a dark or black color to the composition to meet aesthetic industry demands. The carbon black pigment however absorbs infrared and longer wavelengths. The absorption of these longer wavelengths can result in heating and damage to the surface of the resin which can in turn diminish the laser platability, or the metal bonding ability. The compositions of the present disclosure can resolve the damaging effects of the carbon black pigment and provide black or dark colored laser direct structuring compositions which can further exhibit improved metal bonding strength or mechanical properties.

The present disclosure relates to a composition comprising a polymer base substrate, a laser direct structuring additive, a reinforcing filler, and a photopermeable colorant, wherein the composition is black or contains sufficient pigment or colorant to establish a dark color throughout the composition and wherein the composition is capable of metal activation for metal bonding or plating at laser irradiated (or activated) areas of the composition. As such, the laser irradiation can provide a laser activated composition amenable to plating with metal.

In an aspect, the composition can comprise from about 10 wt. % to about 90 wt. % of a polymer base resin, from about 0.1 wt. % to about 60 wt. % of a reinforcing filler, from about 0.1 wt. % to about 10 wt. % of a laser direct structuring additive, and from about 0.01 wt. % to about 10 wt. % of a photopermeable colorant, wherein the combined weight percent value of all components does not exceed about 100 wt. %, wherein all weight percent values are based on the total weight of the composition, and wherein the combined weight percent value of all components does not exceed about 100 wt. %, and wherein all weight percent values are based on the total weight of the composition, wherein the composition can be electrolessly metal plated, wherein the metal plated composition exhibits an average Plating Index at less than 10% difference from a Plating Index of a substantially similar metal plated composition comprising carbon black in the absence of a photopermeable colorant when tested at the same laser intensities; and wherein the composition exhibits a percent transmittance of up to about 20% at from about 190 nm to about 400 nm and a percent transmittance of greater than 50% at from about 700 nm to about 2500 nm.

In some aspects, the present disclosure further relates to a composition comprising: from 10 wt. % to 90 wt. % of a polymer base resin; from 0.1 wt. % to 60 wt. % of a reinforcing filler; from 0.1 wt. % to 10 wt. % of a laser direct structuring additive; and from 0.01 wt. % to 10 wt. % of a photopermeable colorant, wherein the combined weight percent value of all components does not exceed 100 wt. %, and wherein all weight percent values are based on the total weight of the composition, wherein the composition exhibits a change in transmittance of at least 20% between a transmittance observed between 190 nm and 400 nm and a transmittance observed from 700 nm to 2500 nm; and wherein the composition is configured to be activated by laser.

### Polymer Base Resin

In an aspect, the composition can comprise a polymer base resin. In various aspects, the polymer base substrate can comprise a thermoplastic resin or a thermoset resin. The thermoplastic resin can comprise polypropylene, polyethylene, ethylene based copolymer, polycarbonate, polyamide, polyester, polyoxymethylene (POM), polybutylene terephthalate (PBT), polyethylene terephthalate (PET), polycyclohexylendimethylene terephthalate (PCT), liquid crystal polymers (LPC), polyphenylene Sulfide (PPS), polyphenylene ether (PPE), polyphenylene oxide-polystyrene blends, polystyrene, high impact modified polystyrene, acrylonitrile-butadiene-styrene (ABS) terpolymer, acrylic polymer, polyetherimide (PEI), polyurethane, polyetheretherketone (PEEK), poly ether sulphone (PES), and combinations thereof. The thermoplastic resin can also include thermoplastic elastomers such as polyamide and polyester based elastomers. The base substrate can also comprise blends and/or other types of combination of resins described above. In various aspects, the polymer base substrate can also comprise a thermosetting polymer. Appropriate thermosetting resins can include phenol resin, urea resin, melamine-formaldehyde resin, urea-formaldehyde latex, xylene resin, diallyl phthalate resin, epoxy resin, aniline resin, furan resin, polyurethane, or combinations thereof.

In an example, the polymer base substrate can comprise a polycarbonate. For example, the polycarbonate component can comprise bisphenol A, a polycarbonate copolymer, polyester carbonate polymer, or polycarbonate-polysiloxane copolymer, or some combination thereof. In further aspects, the polycarbonate polymer can comprise a mixture of a first polycarbonate and a second polycarbonate.

The terms “polycarbonate” or “polycarbonates” as used herein includes copolycarbonates, homopolycarbonates and (co)polyester carbonates. The term polycarbonate can be further defined as compositions have repeating structural units of the formula (1):

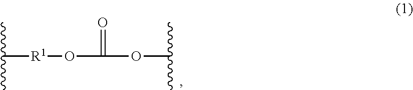

in which at least 60 percent of the total number of R¹ groups are aromatic organic radicals and the balance thereof are aliphatic, alicyclic, or aromatic radicals. In a further aspect, each R¹ is an aromatic organic radical and, more preferably, a radical of the formula (2):

-A¹-Y¹-A²- (2),

wherein each of A¹ and A² is a monocyclic divalent aryl radical and Y¹ is a bridging radical having one or two atoms that separate A¹ from A². In various aspects, one atom separates A¹ from A². For example, radicals of this type include, but are not limited to, radicals such as —O—, —S—, —S(O)—, —S(O₂)—, —C(O)—, methylene, cyclohexyl-methylene, 2-[2.2.1]-bicycloheptylidene, ethylidene, isopropylidene, neopentylidene, cyclohexylidene, cyclopentadecylidene, cyclododecylidene, and adamantylidene. The bridging radical Y¹ is preferably a hydrocarbon group or a saturated hydrocarbon group such as methylene, cyclohexylidene, or isopropylidene. Polycarbonate materials include materials disclosed and described in U.S. Pat. No. 7,786,246, which is hereby incorporated by reference in its entirety for the specific purpose of disclosing various polycarbonate compositions and methods for manufacture of same. Polycarbonate polymers can be manufactured by means known to those skilled in the art.

Specific dihydroxy compounds include aromatic dihydroxy compounds of formula (2) (e.g., resorcinol), bisphenols of formula (3) (e.g., bisphenol A or BPA), a C1-8 aliphatic diol such as ethane diol, n-propane diol, i-propane diol, 1,4-butane diol, 1,6-cyclohexane diol, 1,6-hydroxymethylcyclohexane, or a combination comprising at least one of the foregoing dihydroxy compounds. Aliphatic dicarboxylic acids that can be used include C6-20 aliphatic dicarboxylic acids (which includes the terminal carboxyl groups), specifically linear C8-12 aliphatic dicarboxylic acid such as decanedioic acid (sebacic acid); and alpha, omega-C12 dicarboxylic acids such as dodecanedioic acid (DDDA). Aromatic dicarboxylic acids that can be used include terephthalic acid, isophthalic acid, naphthalene dicarboxylic acid, 1,6-cyclohexane dicarboxylic acid, or a combination comprising at least one of the foregoing acids. A combination of isophthalic acid and terephthalic acid wherein the weight ratio of isophthalic acid to terephthalic acid is 91:9 to 2:98 can be used.

Specific ester units include ethylene terephthalate units, n-propylene terephthalate units, n-butylene terephthalate units, ester units derived from isophthalic acid, terephthalic acid, and resorcinol (ITR ester units), and ester units derived from sebacic acid and bisphenol A. The molar ratio of ester units to carbonate units in the poly(ester-carbonate)s can vary broadly, for example 1:99 to 99:1, specifically, 10:90 to 90:10, more specifically, 25:75 to 75:25, or from 2:98 to 15:85.

The term polycarbonate as used herein is not intended to refer to only a specific polycarbonate or group of polycarbonates, but rather refers to the any one of the class of compounds containing a repeating chain of carbonate groups. In one aspect, a polycarbonate can include any one or more of those polycarbonates disclosed and described in U.S. Pat. No. 7,786,246, which is hereby incorporated by reference in its entirety for the specific purpose of disclosing various polycarbonate compositions and methods for manufacture of same.

The polymer base resin can comprise a polyester-polycarbonate copolymer, and specifically a polyester-polycarbonate copolymer in which the ester units of formula (5) comprise soft block ester units, also referred to herein as aliphatic dicarboxylic acid ester units. Such a polyester-polycarbonate copolymer comprising soft block ester units is also referred to herein as a poly(aliphatic ester)-polycarbonate.

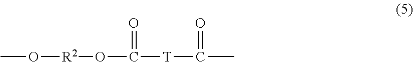

wherein R² is a divalent group derived from a dihydroxy compound, and can be, for example, a C₂₋₁₀ alkylene group, a C₆₋₂₀ alicyclic group, a C₆₋₂₀ aromatic group or a polyoxyalkylene group in which the alkylene groups contain 2 to about 6 carbon atoms, specifically 2, 3, or 4 carbon atoms; and T is a divalent group derived from a dicarboxylic acid (aliphatic, aromatic, or alkyl aromatic), and can be, for example, a C₄₋₁₈ aliphatic group, a C₆₋₂₀ alkylene group, a C₆₋₂₀ alkylene group, a C₆₋₂₀ alicyclic group, a C₆₋₂₀ alkyl aromatic group, or a C₆₋₂₀ aromatic group.

R² can be is a C₂₋₁₀ alkylene group having a straight chain, branched chain, or cyclic (including polycyclic) structure. Alternatively, R² can be derived from an aromatic dihydroxy compound of formula (6), or from an aromatic dihydroxy compound of formula (7).

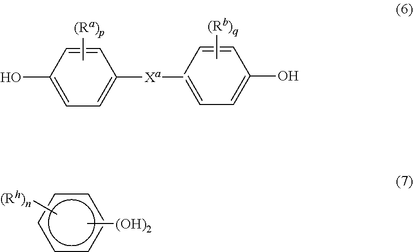

The soft block ester unit can be a C₆₋₂₀ aliphatic dicarboxylic acid ester unit (where C₆₋₂₀ includes the terminal carboxyl groups), and can be straight chain (i.e., unbranched) or branched chain dicarboxylic acids, cycloalkyl or cycloalkylidene-containing dicarboxylic acids units, or combinations of these structural units. In an aspect, the C₆₋₂₀ aliphatic dicarboxylic acid ester unit includes a straight chain alkylene group comprising methylene (—CH₂—) repeating units. In a specific aspect, a useful soft block ester unit comprises units of formula (8):

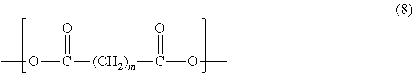

where m is 4 to 18. In a specific aspect of formula (8), m is 8 to 10. The poly(aliphatic ester)-polycarbonate can include less than or equal to 25 wt. % of the soft block unit. In an aspect, a poly(aliphatic ester)-polycarbonate comprises units of formula (1a) in an amount of 0.5 to 10 wt %, specifically 1 to 9 wt. %, and more specifically 3 to 8 wt. %, based on the total weight of the poly(aliphatic ester)-polycarbonate.

Desirably, the poly(aliphatic ester)-polycarbonate has a glass transition temperature (Tg) of 110° C. to 145° C., or about 110° C. to about 145° C., specifically 115° C. to 145° C., or from about 115° C. to about 145° C., more specifically 120 to 145° C., or from about 120° C. to about 145° C., more specifically 128 to 139° C., or from about 128° C. to about 139° C., and still more specifically 130° C. to 139° C. or from about 130° C. to about 139° C.

The molecular weight of any particular polycarbonate can be determined by, for example, gel permeation chromatography using universal calibration methods based on polystyrene (PS) standards. Generally polycarbonates can have a weight average molecular weight (Mw), of greater than 5,000 grams per mol (g/mol), or about 5,000 g/mol, based on PS standards. In one aspect, the polycarbonates can have an Mw of greater than or equal to 20,000 g/mol, or about 20,000 g/mol, based on PS standards. In another aspect, the polycarbonates have an Mw based on PS standards of 20,000 g/mol to 100,000 g/mol, or from about 20,000 to about 100,000 g/mol, including for example 30,000 g/mol, or about 30,000 g/mol, 40,000 g/mol, or about 40,000 g/mol, 50,000 g/mol, or about 50,000 g/mol, 60,000 g/mol, or about 60,000 g/mol, 70,000 g/mol, or about 70,000 g/mol, 80,000 g/mol, or about 80,000 g/mol, or 90,000 g/mol, or about 90,000 g/mol. In still further aspects, the polycarbonates have an Mw based on PS standards of 22,000 g/mol to 50,000 g/mol, or from about 22,000 to about 50,000 g/mol. In still further aspects, the polycarbonates have an Mw based on PS standards of 25,000 g/mol to 40,000 g/mol, or from about 25,000 to about 40,000 g/mol.

Molecular weight (Mw and Mn) as described herein, and polydispersity as calculated therefrom, can be determined using gel permeation chromatography (GPC), using a crosslinked styrene-divinylbenzene column, and either PS or PC standards as specified. GPC samples can be prepared in a solvent such as methylene chloride or chloroform at a concentration of about 1 milligram per milliliter (mg/ml), and can be eluted at a flow rate of about 0.2 to 1.0 ml/min. In one aspect, the glass transition temperature (Tg) of a polycarbonate can be less than or equal to 160° C., or about 160° C., less than or equal to 150° C., or less than or equal to about 150° C., less than or equal to 145° C., or less than or equal to about 145° C., less than or equal to 140° C., or less than or equal to about 140° C., or less than or equal to 135° C., or less than or equal to about 135° C. In a further aspect, the glass transition temperature of a polycarbonate can be from 85° C. to 160° C., or from about 85° C. to about 160° C., from 90° C. to 160° C., or from about 90° C. to about 160° C., 90° C. to 150° C., or from about 90° C. to about 150° C., or from 90° C. to 145° C., or about 90° C. to about 145° C. In a still further aspect, the glass transition temperature of a polycarbonate can be from 85° C. to 130° C., from 90° C. to 130° C., from 90° C. to 125° C., or from 90° C. to about 120° C. In a yet further aspect, the glass transition temperature of a polycarbonate can be from about 85° C. to about 130° C., from about 90° C. to about 130° C., from about 90° C. to about 125° C., or from about 90° C. to about 120° C.

The poly(aliphatic ester-carbonate) can have a weight average molecular weight of 15,000 Daltons to 40,000 Daltons, or from about 15,000 Daltons to about 40,000 Daltons, including from 20,000 Daltons to 38,000 Daltons, or from about 20,000 Daltons to about 38,000 Daltons (measured by GPC based on BPA polycarbonate standards).

In addition to the polycarbonates described above, combinations of the polycarbonate with other thermoplastic polymers, for example combinations of homopolycarbonates, copolycarbonates, and polycarbonate copolymers with polyesters, can be used. Useful polyesters include, for example, polyesters having repeating units of formula (7), which include poly(alkylene dicarboxylates), liquid crystalline polyesters, and polyester copolymers. The polyesters described herein can generally be completely miscible with the polycarbonates when blended.

Useful polyesters can include aromatic polyesters, poly(alkylene esters) including poly(alkylene arylates), and poly(cycloalkylene diesters). Aromatic polyesters can have a polyester structure according to formula (7), wherein J and T are each aromatic groups as described above. In an embodiment, useful aromatic polyesters can include poly(isophthalate-terephthalate-resorcinol) esters, poly(isophthalate-terephthalate-bisphenol A) esters, poly[(isophthalate-terephthalate-resorcinol) ester-co-(isophthalate-terephthalate-bisphenol A)]ester, or a combination comprising at least one of these. Also contemplated are aromatic polyesters with a minor amount, e.g., 0.5 wt. % to 10 wt. %, or from about 0.5 wt. % to about 10 wt. %, based on the total weight of the polyester, of units derived from an aliphatic diacid and/or an aliphatic polyol to make copolyesters. Poly(alkylene arylates) can have a polyester structure according to formula (7), wherein T comprises groups derived from aromatic dicarboxylates, cycloaliphatic dicarboxylic acids, or derivatives thereof.

Copolymers comprising alkylene terephthalate repeating ester units with other ester groups can also be useful. Specifically useful ester units can include different alkylene terephthalate units, which can be present in the polymer chain as individual units, or as blocks of poly(alkylene terephthalates). Copolymers of this type include poly(cyclohexanedimethylene terephthalate)-co-poly(ethylene terephthalate), abbreviated as PETG where the polymer comprises greater than or equal to 50 mol percent (mol %) of poly(ethylene terephthalate), and abbreviated as PCTG where the polymer comprises greater than 50 mol % of poly(1,4-cyclohexanedimethylene terephthalate).

The composition can further comprise a polysiloxane-polycarbonate copolymer, also referred to as a poly(siloxane-carbonate). The polydiorganosiloxane (also referred to herein as “polysiloxane”) blocks comprise repeating diorganosiloxane units as in formula (9)

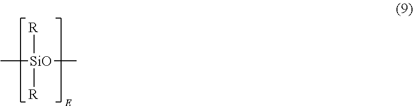

wherein each R is independently a C₁₋₁₃ monovalent organic group. For example, R can be a C₁-C₁₃ alkyl, C₁-C₁₃ alkoxy, C₂-C₁₃ alkenyl, C₂-C₁₃ alkenyloxy, C₃-C₆ cycloalkyl, C₃-C₆ cycloalkoxy, C₆-C₁₄ aryl, C₆-C₁₀ aryloxy, C₇-C₁₃ arylalkyl, C₇-C₁₃ aralkoxy, C₇-C₁₃ alkylaryl, or C₇-C₁₃ alkylaryloxy. The foregoing groups can be fully or partially halogenated with fluorine, chlorine, bromine, or iodine, or a combination thereof. In an embodiment, where a transparent polysiloxane-polycarbonate is desired, R is unsubstituted by halogen. Combinations of the foregoing R groups can be used in the same copolymer.

A combination of a first and a second (or more) polycarbonate-polysiloxane copolymers can be used, wherein the average value of E of the first copolymer is less than the average value of E of the second copolymer.

In an aspect, the polydiorganosiloxane blocks are of formula (10)

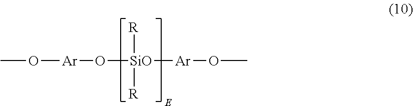

wherein E is as defined above; each R can be the same or different, and is as defined above; and Ar can be the same or different, and is a substituted or unsubstituted C₆-C₃₀ arylene, wherein the bonds are directly connected to an aromatic moiety. Ar groups in formula (13) can be derived from a C₆-C₃₀ dihydroxyarylene compound, for example a dihydroxyarylene compound of formula (3) or (6) above. Dihydroxyarylene compounds are 1,1-bis(4-hydroxyphenyl) methane, 1,1-bis(4-hydroxyphenyl) ethane, 2,2-bis(4-hydroxyphenyl) propane, 2,2-bis(4-hydroxyphenyl) butane, 2,2-bis(4-hydroxyphenyl) octane, 1,1-bis(4-hydroxyphenyl) propane, 1,1-bis(4-hydroxyphenyl) n-butane, 2,2-bis(4-hydroxy-1-methylphenyl) propane, 1,1-bis(4-hydroxyphenyl)cyclohexane, bis(4-hydroxyphenyl sulfide), and 1,1-bis(4-hydroxy-t-butylphenyl) propane. Combinations comprising at least one of the foregoing dihydroxy compounds can also be used.

In another aspect, polydiorganosiloxane blocks can be of formula (11)

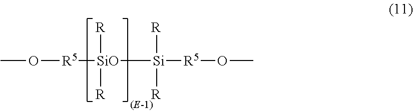

wherein R and E are as described above, and each R⁵ is independently a divalent C₁-C₃₀ organic group, and wherein the polymerized polysiloxane unit is the reaction residue of its corresponding dihydroxy compound. In one aspect, the polydiorganosiloxane blocks are of formula (12):

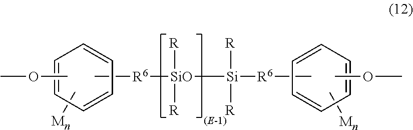

wherein R and E are as defined above. R⁶ in formula (12) is a divalent C₂-C₈ aliphatic. Each M in formula (15) can be the same or different, and can be a halogen, cyano, nitro, C₁-C₅ alkylthio, C₁-C₈ alkyl, C₁-C₅ alkoxy, C₂-C₈ alkenyl, C₂-C₈ alkenyloxy, C₃-C₈ cycloalkyl, C₃-C₈ cycloalkoxy, C₆-C₁₀ aryl, C₆-C₁₀ aryloxy, C₇-C₁₂ aralkyl, C₇-C₁₂ aralkoxy, C₇-C₁₂ alkylaryl, or C₇-C₁₂ alkylaryloxy, wherein each n is independently 0, 1, 2, 3, or 4.

The polysiloxane-polycarbonate copolymers can comprise 50 wt. % to 99 wt. %, or from about 50 wt. % to about 99 wt. %, of carbonate units and 1 wt. % to 50 wt. %, or from about 1 wt. % to about 50 wt. %, siloxane units. Within this range, the polyorganosiloxane-polycarbonate copolymer can comprise 70 wt. %, to 98 wt. %, more specifically 75 wt. % to 97 wt. % of carbonate units and 2 wt. % to 30 wt. %, more specifically 3 wt. % to 25 wt. % siloxane units. In some examples, the polyorganosiloxane-polycarbonate copolymer can comprise about 70 wt. %, to about 98 wt. %, more specifically about 75 wt. % to about 97 wt. % of carbonate units and about 2 wt. % to about 30 wt. %, more specifically about 3 wt. % to about 25 wt. % siloxane units.

In some aspects, a blend can be used, in particular a blend of a bisphenol A homopolycarbonate and a polysiloxane-polycarbonate block copolymer of bisphenol A blocks and eugenol capped polydimethylsilioxane blocks, of the formula (13)

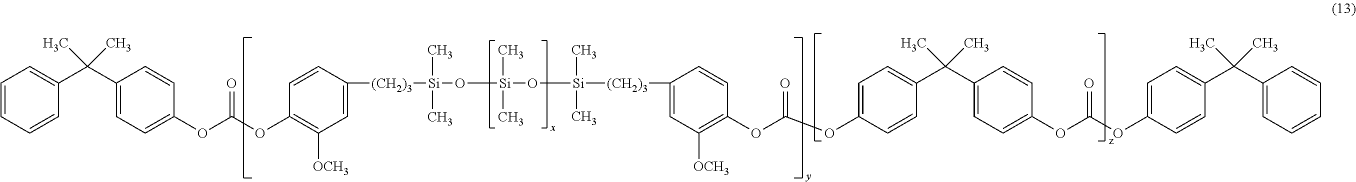

wherein x is 1 to 200, specifically 5 to 85, specifically 10 to 70, specifically 15 to 65, and more specifically 40 to 60; x is 1 to 500, or 10 to 200, and z is 1 to 1000, or 10 to 800. In an embodiment, x is 1 to 200, y is 1 to 90 and z is 1 to 600, and in another embodiment, x is 30 to 50, y is 10 to 30 and z is 45 to 600. The polysiloxane blocks may be randomly distributed or controlled distributed among the polycarbonate blocks.

In one aspect, the polysiloxane-polycarbonate copolymer can comprise 10 wt % or less, or about 10 wt. % or less, specifically 6 wt. % or less, or about 6 wt. % or less, and more specifically 4 wt. % or less, or about 4 wt. % or less of the polysiloxane based on the total weight of the polysiloxane-polycarbonate copolymer, and can generally be optically transparent and are commercially available under the designation EXL-T™ from SABIC™. In another aspect, the polysiloxane-polycarbonate copolymer can comprise 10 wt % or more, or about 10 wt. % or more, specifically 12 wt. % or more, or about 12 wt. % or more, and more specifically 14 wt. % or more, or about 14 wt. % or more, of the polysiloxane copolymer based on the total weight of the polysiloxane-polycarbonate copolymer, are generally optically opaque and are commercially available under the trade designation EXL-P™ from SABIC™.

Polyorganosiloxane-polycarbonates can have a weight average molecular weight of 2,000 Daltons to 100,000 Daltons or about 2,000 Daltons to about 100,000 Daltons, specifically 5,000 Daltons to 50,000 Daltons, or about 5,000 Daltons or about 50,000 Daltons, as measured by gel permeation chromatography using a crosslinked styrene-divinyl benzene column, at a sample concentration of 1 milligram per milliliter (1 mg/ml), and as calibrated with polycarbonate standards.

The polyorganosiloxane-polycarbonates can have a melt volume flow rate, measured at 300° C./1.2 kilogram (kg), of 1 cubic centimeters per 10 minutes (cm³/10 min) to 50 cm³/10 min, specifically 2 to 30 cm³/10 min. Mixtures of polyorganosiloxane-polycarbonates of different flow properties can be used to achieve the overall desired flow property. In some examples, the polyorganosiloxane-polycarbonates can have a melt volume flow rate, measured at 300° C./1.2 kg, of about 1 cm³/10 min to about 50 cm³/10 min, specifically about 2 to about 30 cm³/10 min.

In an aspect, polyetherimides can be used in the disclosed compositions and can be of formula (14):

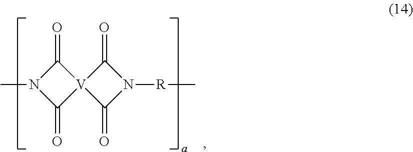

wherein a is more than 1, for example 10 to 1,000 or more, or more specifically 10 to 500.

The group V in formula (16) is a tetravalent linker containing an ether group (a “polyetherimide” as used herein) or a combination of an ether groups and arylenesulfone groups (a “polyetherimidesulfone”). Such linkers include but are not limited to: (a) substituted or unsubstituted, saturated, unsaturated or aromatic monocyclic and polycyclic groups having 5 to 50 carbon atoms, optionally substituted with ether groups, arylenesulfone groups, or a combination of ether groups and arylenesulfone groups; and (b) substituted or unsubstituted, linear or branched, saturated or unsaturated alkyl groups having 1 to 30 carbon atoms and optionally substituted with ether groups or a combination of ether groups, arylenesulfone groups, and arylenesulfone groups; or combinations comprising at least one of the foregoing. Suitable additional substitutions include, but are not limited to, ethers, amides, esters, and combinations comprising at least one of the foregoing.

The R group in formula (14) can include but is not limited to substituted or unsubstituted divalent organic groups such as: (a) aromatic hydrocarbon groups having 6 to 20 carbon atoms and halogenated derivatives thereof; (b) straight or branched chain alkylene groups having 2 to 20 carbon atoms; (c) cycloalkylene groups having 3 to 20 carbon atoms, or (d) divalent groups of formula (15):

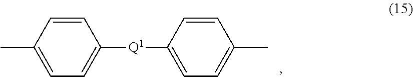

wherein Q1 includes but is not limited to a divalent moiety such as —O—, —S—, —C(O)—, —SO₂—, —SO—, —C_{y}H_{2y}— (y being an integer from 1 to 5), and halogenated derivatives thereof, including perfluoroalkylene groups.

In an aspect, linkers V can include but are not limited to tetravalent aromatic groups of formula (16):

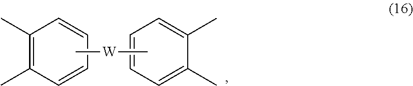

wherein W is a divalent moiety including —O—, —SO₂—, or a group of the formula —O—Z—O— wherein the divalent bonds of the —O— or the —O—Z—O— group are in the 3,3′, 3,4′, 4,3′, or the 4,4′ positions, and wherein Z includes, but is not limited, to divalent groups of formulas (17):

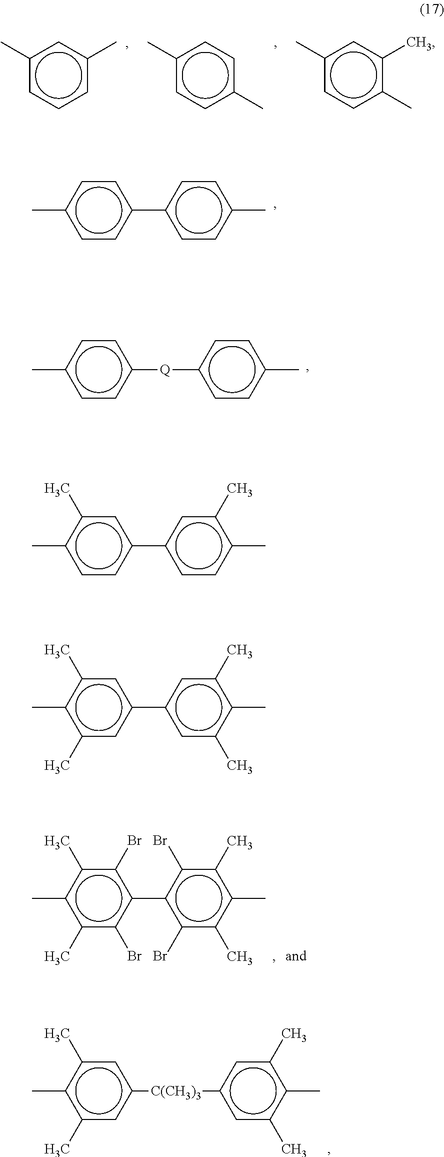

wherein Q can include, but is not limited to a divalent moiety including —O—, —S—, —C(O), —SO₂—, —SO—, —C_{y}H_{2y}— (y being an integer from 1 to 5), and halogenated derivatives thereof, including perfluoroalkylene groups.

In an aspect, the polyetherimide can comprise more than 1, specifically 10 to 1,000, or more specifically, 10 to 500 structural units, of formula (18):

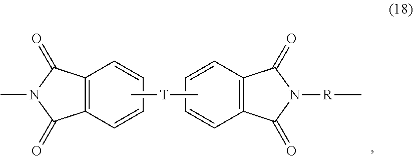

wherein T is —O— or a group of the formula —O—Z—O— wherein the divalent bonds of the —O— or the —O—Z—O— group are in the 3,3′, 3,4′, 4,3′, or the 4,4′ positions; Z is a divalent group of formula (14) as defined above; and R is a divalent group of formula (14) as defined above.

In another aspect, the polyetherimidesulfones can be polyetherimides comprising ether groups and sulfone groups wherein at least 50 mole % of the linkers V and the groups R in formula (1) comprise a divalent arylenesulfone group. For example, all linkers V, but no groups R, can contain an arylenesulfone group; or all groups R but no linkers V can contain an arylenesulfone group; or an arylenesulfone can be present in some fraction of the linkers V and R groups, provided that the total mole fraction of V and R groups containing an aryl sulfone group is greater than or equal to 50 mole %.

Even more specifically, polyetherimidesulfones can comprise more than 1, specifically 10 to 1,000, or more specifically, 10 to 500 structural units of formula (19):

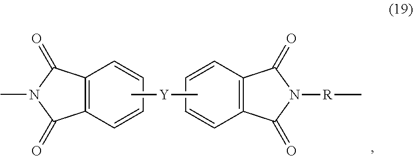

wherein Y is —O—, —SO₂—, or a group of the formula —O—Z—O— wherein the divalent bonds of the —O—, SO₂—, or the —O—Z—O— group are in the 3,3′, 3,4′, 4,3′, or the 4,4′ positions, wherein Z is a divalent group of formula (14) as defined above and R is a divalent group of formula (12) as defined above, provided that greater than 50 mole % of the sum of moles Y+moles R in formula (12) contain —SO₂— groups.

The polyetherimide resin can have a weight average molecular weight (Mw) within a range having a lower limit and/or an upper limit. The range can include or exclude the lower limit and/or the upper limit. The polyetherimide resin can have a molecular weight from 5,000 Daltons to 110,000 Daltons, or from about 5,000 Daltons to about 110,000 Daltons. For example, the polyetherimide resin can have a weight average molecular weight (Mw) from 5,000 Daltons to 100,000 Daltons, or from about 5,000 Daltons to about 100,000 Daltons, or from 5,000 Daltons to 80,000 Daltons, or from about 5,000 Daltons to about 80,000 Daltons, or from 5,000 Daltons to 70,000 Daltons, or from about 5,000 Daltons to about 70,000 Daltons. The primary alkyl amine modified polyetherimide will have lower molecular weight and higher melt flow than the starting, unmodified, polyetherimide.

The polyetherimide resin can be selected from the group consisting of a polyetherimide, for example, as described in U.S. Pat. Nos. 3,875,116, 6,919,422, and 6,355,723; a silicone polyetherimide, for example, as described in U.S. Pat. Nos. 4,690,997 and 4,808,686; a polyetherimidesulfone resin, as described in U.S. Pat. No. 7,041,773; or combinations thereof. Each of these patents are incorporated herein in their entirety.

The polyetherimide resin can have a glass transition temperature within a range having a lower limit and/or an upper limit. The range can include or exclude the lower limit and/or the upper limit. The polyetherimide resin can have a glass transition temperature of from 100° C. to 10° C., or from about 100° C. to about 310° C. For example, the polyetherimide resin can have a glass transition temperature (Tg) greater than 200° C., or about 200° C. The polyetherimide resin can be substantially free (less than 100 parts per million, ppm) of benzylic protons. The polyetherimide resin can be free of benzylic protons. The polyetherimide resin can have an amount of benzylic protons below 100 ppm, or below about 100 ppm. In one aspect, the amount of benzylic protons ranges from more than 0 ppm to below 100 ppm, or below about 100 ppm. In another aspect, the amount of benzylic protons is not detectable. The polyetherimide resin can be substantially free (less than 100 ppm) of halogen atoms. The polyetherimide resin can be free of halogen atoms. The polyetherimide resin can have an amount of halogen atoms below 100 ppm. In one embodiment, the amount of halogen atoms range from more than 0 to below 100 ppm. In another embodiment, the amount of halogen atoms is not detectable.

In one aspect, the polymer base resin can comprise a polyamide polymer. In a further aspect, the polyamide polymer component can comprise a single polyamide or, alternatively, in another aspect can comprise a blend of two or more different polyamides. In one aspect, the polyamide polymer component can be nylon 6.

As noted herein, the polymer base resin can comprise a number of thermoplastic resins, or a combination thereof. In one example, the polymer base resin can comprise a polycarbonate copolymer comprising units derived from BPA, or a mixture of one or more polycarbonate copolymers comprising units derived from BPA. In a specific example, the polymer base resin can comprise a polycarbonate copolymer having units derived from BPA and a poly(aliphatic ester)-polycarbonate copolymer derived from sebacic acid.

In further examples, a polycarbonate of the polymer base resin can comprise a branched polycarbonate. An exemplary branching agent can include, but is not limited to 1,1,1-tris(4-hydroxyphenyl)ethane (THPE). As a further example, the branched polycarbonate resin may be endcapped with an appropriate end-capping agent, such as for example, p-cyanolphenol (known as HBN).

### Reinforcing Filler

The compositions of the present disclosure can comprise a reinforcing filler. Exemplary reinforcing fillers can include glass fiber, carbon fiber, a mineral filler, or a combination thereof. For example, the reinforcing filler can include mica, clay, feldspar, quartz, quartzite, perlite, tripoli, diatomaceous earth, aluminum silicate (mullite), synthetic calcium silicate, fused silica, fumed silica, sand, boron-nitride powder, boron-silicate powder, calcium sulfate, calcium carbonates (such as chalk, limestone, marble, and synthetic precipitated calcium carbonates) talc (including fibrous, modular, needle shaped, and lamellar talc), wollastonite, hollow or solid glass spheres, silicate spheres, cenospheres, aluminosilicate or (armospheres), kaolin, whiskers of silicon carbide, alumina, boron carbide, iron, nickel, or copper, continuous and chopped carbon fibers or glass fibers, molybdenum sulfide, zinc sulfide, barium titanate, barium ferrite, barium sulfate, heavy spar, TiO₂, aluminum oxide, magnesium oxide, particulate or fibrous aluminum, bronze, zinc, copper, or nickel, glass flakes, flaked silicon carbide, flaked aluminum diboride, flaked aluminum, steel flakes, natural fillers such as wood flour, fibrous cellulose, cotton, sisal, jute, starch, lignin, ground nut shells, or rice grain husks, reinforcing organic fibrous fillers such as poly(ether ketone), polyimide, polybenzoxazole, poly(phenylene sulfide), polyesters, polyethylene, aromatic polyamides, aromatic polyimides, polyetherimides, polytetrafluoroethylene, and poly(vinyl alcohol), as well combinations comprising at least one of the foregoing fillers or reinforcing agents. Fillers generally can be used in amounts of 1 to 200 parts by weight, based on 100 parts by weight of based on 100 parts by weight of the total composition.

The fillers and reinforcing agents may be surface treated to deliver certain properties or to increase compatibility with the composition. Generally, a metallic material may be coated upon the filler to facilitate conductivity, or a silane may be deposited on the filler surface to improve adhesion and dispersion with the polymer matrix. Thus in one example, the filler can comprise glass fibers coated with silanes.

The glass fiber can also be surface-treated with a surface treatment agent containing a coupling agent. Appropriate coupling agents can include, but are not limited to, silane-based coupling agents, titanate-based coupling agents or a mixture thereof. Suitable silane-based coupling agents can include aminosilane, epoxysilane, amidesilane, azidesilane and acrylsilane.

The glass fiber can have a round or flat cross section, or some combination thereof. As such, the composition may comprise both glass fibers with round cross sections and glass fibers with flat cross sections. For example, the glass fiber can have a round cross section with a diameter of from 10 micrometers (μm) to 20 μm, or from about 10 μm to about 20 μm. In an example, the glass fiber can have a diameter of 13 μm, or about 13 μm. In further aspects, the glass fibers can have a pre-compounded length of from 0.1 millimeters (mm) to 20 mm, or from about 0.1 mm to about 20 mm. As an example, the glass fibers can have a pre-compounded length of 4 millimeters (mm), or about 4 mm. In some aspects of the disclosed composition, the glass fibers can have a length of 2 mm or longer, or about 2 mm or longer.

### Laser Direct Structuring Additive

In addition to the polymer base resin and reinforcing filler, the compositions of the present disclosure can also include a laser direct structuring (LDS) additive. The LDS additive is selected to enable the composition to be used in a laser direct structuring process. In an LDS process, a laser beam exposes the LDS additive to place it at the surface of the thermoplastic composition and to activate metal atoms from the LDS additive. As such, the LDS additive is selected such that, upon exposed to a laser beam, metal atoms are activated and exposed and in areas not exposed by the laser beam, no metal atoms are exposed. In addition, the LDS additive is selected such that, after being exposed to laser beam, the etching area is capable of being plated to form conductive structure. As used herein “capable of being plated” refers to a material wherein a substantially uniform metal plating layer can be plated on laser-etched area and show a wide window for laser parameters.

Examples of LDS additives useful in the present disclosure include, but are not limited to, a heavy metal mixture oxide spinel, such as copper chromium oxide spinel; a copper salt, such as copper hydroxide phosphate copper phosphate, copper sulfate, cuprous thiocyanate, spinel based metal oxides (such as copper chromium oxide), organic metal complexes (such as palladium/palladium-containing heavy metal complexes), metal oxides, metal oxide-coated fillers, antimony doped tin oxide coated on a mica substrate, a copper containing metal oxide, a zinc containing metal oxide, a tin containing metal oxide, a magnesium containing metal oxide, an aluminum containing metal oxide, a gold containing metal oxide, a silver containing metal oxide, or the like; or a combination including at least one of the foregoing LDS additives.

In one example, the laser direct structuring additive can be present in an amount from 1.0 wt. % to 10 wt. %, or from about 1.0 wt. % to about 10 wt. %. In a still further example, the laser direct structuring additive can be present in an amount from 0.5 wt. % to 5 wt. %, or from about 0.5 wt. % to about 5 wt. %.

As discussed, the LDS additive is selected such that, after activation with a laser, the conductive path can be formed by a standard electroless plating process. An electroless plating process can utilize a redox reaction to deposit metal onto an object without the passage of an electric current. The process can allow a constant metal ion concentration to bathe all parts of an object to be plated. As an example, electroless plating can be used to deposit metal evenly along edges, inside holes, and over irregularly shaped objects which can be difficult to plate evenly with electroplating. In the present disclosure, when an LDS additive is exposed to a laser, elemental metal can be released. The laser draws the pattern onto the material (for example, a resin) containing the additive and leaves behind a roughened surface containing embedded metal particles. These particles can act as nuclei for the crystal growth during a subsequent electroless plating process, such as an electroless copper plating process. Other electroless plating processes that may be used include, but are not limited to, gold plating, nickel plating, silver plating, zinc plating, tin plating or the like.

### Photopermeable Colorant

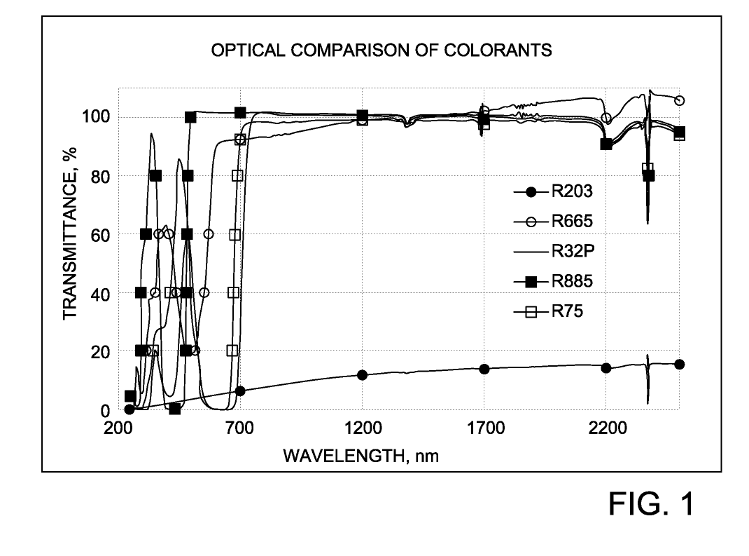

The compositions of the present disclosure can comprise a photopermeable colorant. A photopermeable colorant can refer to a colorant that exhibits weak light absorption, or high transmittance, particularly at increasing wavelengths. That is, a photopermeable colorant can have a percent transmittance of greater than about 60% at greater than 700 nm wavelength. The photopermeable colorant can also have a percent transmittance of greater than about 60% at a wavelength used for irradiating a material surface during an LDS process. With respect to FIG. 1 showing transmittance of several colorants, one skilled in the art might appreciate that at the laser wavelength of LDS, for example 1064 nm, only carbon black R203 has low transmittance at about 10%. Meanwhile pigments R665 (solvent red 135), R32P (solvent green 3), R885 (disperse yellow), R75 (solvent blue 104) all have higher transmittance (about 65% for R665, about 100% for R32P, R885, R75). As such, the colorants solvent red, solvent green, solvent blue, and disperse yellow are photopermeable in that they exhibit color, but do not hinder the transmission of light beyond the UV-VIS and NIR ranges, that is, at greater than 700 nm. As an example, the photopermeable colorant of the present disclosure can have a transmittance of greater than 60 wt. %, or greater than about 60%, at 1064 nm.

In further examples, the photopermeable colorant can be black or dark colored. In still further examples, the photopermeable colorant can be combined with another photopermeable colorant to achieve a dark or a black color. A visibly dark or black color can be characterized by a percent transmittance of up to about 20% at from about 190 nm to about 400 nm. Exemplary photopermeable colorants can include, but are not limited to, solvent red, solvent green, solvent blue, and disperse yellow. The exemplary photopermeable colorants can be combined in total, or in a combination of two or more such that the resultant mixture does not absorb substantial light at the near infrared region of the electromagnetic spectrum and above. That is, in certain embodiments, the resultant mixture does not absorb light at wavelengths longer than about 600 nm. In further embodiments, the resultant mixture may not absorb light at wavelengths longer than about 700 nm. Still, when combined or selectively combined, the photopermeable colorants can form a visually black (or dark) mixture. Moreover, given that the photopermeable colorants do not absorb substantial light at the infrared region, the mixture does not absorb light at 1064 nm, a wavelength used to irradiate a material in a given laser platable process. As such, the compositions described herein may be configured to be photopermeable at specific wavelengths and or ranges, for example, by including loadings of photopermeable colorants. The disclosed compositions are thus advantageous for laser plating processes as the compositions limit the absorption of longer, potentially damaging wavelengths.

In some aspects, the photopermeable colorant may be present in an amount between 0.01 wt. % and 10 wt. %, or between about 0.01 wt. % and about 10 wt. %. Further, the photopermeable colorant may be present in an amount between 0.01 wt. % and 5 wt. %, or between about 0.01 wt. % and about 5 wt. %.

### Additives

The composition can further comprise other additives. Exemplary additives can include ultraviolet (UV) agents, ultraviolet stabilizers, heat stabilizers, antistatic agents, anti-microbial agents, impact modifiers, anti-drip agents, radiation stabilizers, pigments, dyes, fibers, fillers, plasticizers, fibers, flame retardants, antioxidants, lubricants, wood, glass, and metals, and combinations thereof.

As an example, the disclosed composition can comprise an impact modifier. The impact modifier can be a chemically reactive impact modifier. By definition, a chemically reactive impact modifier can have at least one reactive group such that when the impact modifier is added to a polymer composition, the impact properties of the composition (expressed in the values of the Izod impact) are improved. In some examples, the chemically reactive impact modifier can be an ethylene copolymer with reactive functional groups selected from, but not limited to, anhydride, carboxyl, hydroxyl, and epoxy.

In further aspects of the present disclosure, the composition can comprise a rubbery impact modifier. The rubber impact modifier can be a polymeric material which, at room temperature, is capable of recovering substantially in shape and size after removal of a force. However, the rubbery impact modifier should typically have a glass transition temperature of less than 0° C., or less than about. In certain aspects, the glass transition temperature (Tg) can be less than −5° C., −10° C., −15° C., with a Tg of less than −30° C. typically providing better performance. In further aspects, the glass transition temperature (Tg) can be less than about −5° C., about −10° C., about −15° C., with a Tg of less than about −30° C. Representative rubbery impact modifiers can include, for example, functionalized polyolefin ethylene-acrylate terpolymers, such as ethylene-acrylic esters-maleic anhydride (MAH) or glycidyl methacrylate (GMA). The functionalized rubbery polymer can optionally contain repeat units in its backbone which are derived from an anhydride group containing monomer, such as maleic anhydride. In another scenario, the functionalized rubbery polymer can contain anhydride moieties which are grafted onto the polymer in a post polymerization step.

In one example, the composition can comprise a core-shell copolymer impact modifier having about 80 wt. % of a core comprising poly(butyl acrylate) and about 20 wt. % of a shell comprising poly(methyl methacrylate). In a further example, the impact modifier can comprise an acrylic impact modifier such as ethylene-ethylacrylate copolymer with an ethyl acrylate content of less than 20 wt. % (such as EXL 3330™ as supplied by SABIC™). The composition can comprise 5 wt. %, or about 5 wt. %, of the ethylene-ethylacrylate copolymer.

The compositions described herein can further comprise an ultraviolet (UV)stabilizer for dispersing UV radiation energy. UV stabilizers can include but are not limited to, hydroxybenzophenones; hydroxyphenyl benzotriazoles; cyanoacrylates; oxanilides; or hydroxyphenyl triazines.

The composition can comprise heat stabilizers such as, for example, organophosphites including triphenyl phosphite, tris-(2,6-dimethylphenyl)phosphite, tris-(mixed mono- and di-nonylphenyl)phosphite or the like; phosphonates such as dimethylbenzene phosphonate or the like; phosphates such as trimethyl phosphate, or the like; or combinations thereof.

The compositions described herein can further comprise an antistatic agent. Examples of monomeric antistatic agents may include glycerol monostearate, glycerol distearate, glycerol tristearate, ethoxylated amines, primary, secondary and tertiary amines, ethoxylated alcohols, alkyl sulfates, alkylarylsulfates, alkylphosphates, alkylaminesulfates, alkyl sulfonate salts such as sodium stearyl sulfonate, sodium dodecylbenzenesulfonate or the like, quaternary ammonium salts, quaternary ammonium resins, imidazoline derivatives, sorbitan esters, ethanolamides, betaines, or the like, or combinations comprising at least one of the foregoing monomeric antistatic agents.

Exemplary polymeric antistatic agents may include certain polyesteramides polyether-polyamide (polyetheramide) block copolymers, polyetheresteramide block copolymers, polyetheresters, or polyurethanes, each containing polyalkylene glycol moieties polyalkylene oxide units such as polyethylene glycol, polypropylene glycol, polytetramethylene glycol, and the like. Such polymeric antistatic agents are commercially available, for example PELESTAT™ 6321 (Sanyo) or PEBAX™ MH1657 (Atofina), IRGASTAT™ P18 and P22 (Ciba-Geigy). Other polymeric materials may be used as antistatic agents are inherently conducting polymers such as polyaniline (commercially available as PANIPOL™EB from Panipol), polypyrrole and polythiophene (commercially available from Bayer), which retain some of their intrinsic conductivity after melt processing at elevated temperatures. Carbon fibers, carbon nanofibers, carbon nanotubes, carbon black, or a combination comprising at least one of the foregoing may be included to render the compositions described herein electrostatically dissipative.

The compositions described herein can comprise anti-drip agents. The anti-drip agent may be a fibril forming or non-fibril forming fluoropolymer such as polytetrafluoroethylene (PTFE). The anti-drip agent can be encapsulated by a rigid copolymer as described above, for example styrene-acrylonitrile copolymer (SAN) forming the encapsulated polymer commonly known as TSAN. An exemplary TSAN can comprise 50 wt % PTFE and 50 wt % SAN, based on the total weight of the encapsulated fluoropolymer. The SAN can comprise, for example, 75 wt % styrene and 25 wt % acrylonitrile based on the total weight of the copolymer.

The compositions described herein can further comprise a radiation stabilizer, such as a gamma-radiation stabilizer. Exemplary gamma-radiation stabilizers include alkylene polyols such as ethylene glycol, propylene glycol, 1,3-propanediol, 1,2-butanediol, 1,4-butanediol, meso-2,3-butanediol, 1,2-pentanediol, 2,3-pentanediol, 1,4-pentanediol, 1,4-hexandiol, and the like; cycloalkylene polyols such as 1,2-cyclopentanediol, 1,2-cyclohexanediol, and the like; branched alkylenepolyols such as 2,3-dimethyl-2,3-butanediol (pinacol), and the like, as well as alkoxy-substituted cyclic or acyclic alkanes. Unsaturated alkenols are also useful, examples of which include 4-methyl-4-penten-2-ol, 3-methyl-pentene-3-ol, 2-methyl-4-penten-2-ol, 2,4-dimethyl-4-penten-2-ol, and 9 to decen-1-ol, as well as tertiary alcohols that have at least one hydroxy substituted tertiary carbon, for example 2-methyl-2,4-pentanediol (hexylene glycol), 2-phenyl-2-butanol, 3-hydroxy-3-methyl-2-butanone, 2-phenyl-2-butanol, and the like, and cyclic tertiary alcohols such as 1-hydroxy-1-methyl-cyclohexane. The term “pigments” means colored particles that are insoluble in the resulting compositions described herein.

Plasticizers, lubricants, and mold release agents can be included. Mold release agent (MRA) will allow the material to be removed quickly and effectively. Mold releases can reduce cycle times, defects, and browning of finished product. There is considerable overlap among these types of materials, which may include, for example, phthalic acid esters such as dioctyl-4,5-epoxy-hexahydrophthalate; tris-(octoxycarbonylethyl)isocyanurate; tristearin; di- or polyfunctional aromatic phosphates such as resorcinol tetraphenyl diphosphate (RDP), the bis(diphenyl)phosphate of hydroquinone and the bis(diphenyl)phosphate of bisphenol-A; poly-alpha-olefins; epoxidized soybean oil; silicones, including silicone oils; esters, for example, fatty acid esters such as alkyl stearyl esters, e.g., methyl stearate, stearyl stearate, pentaerythritol tetrastearate (PETS), and the like; combinations of methyl stearate and hydrophilic and hydrophobic nonionic surfactants comprising polyethylene glycol polymers, polypropylene glycol polymers, poly(ethylene glycol-co-propylene glycol) copolymers, or a combination comprising at least one of the foregoing glycol polymers, e.g., methyl stearate and polyethylene-polypropylene glycol copolymer in a suitable solvent; waxes such as beeswax, montan wax, paraffin wax, or the like.

Various types of flame retardants can be utilized as additives. In one embodiment, the flame retardant additives include, for example, flame retardant salts such as alkali metal salts of perfluorinated C₁-C₁₆ alkyl sulfonates such as potassium perfluorobutane sulfonate (Rimar salt), potassium perfluoroctane sulfonate, tetraethylammonium perfluorohexane sulfonate, potassium diphenylsulfone sulfonate (KSS), and the like, sodium benzene sulfonate, sodium toluene sulfonate (NATS) and the like; and salts formed by reacting for example an alkali metal or alkaline earth metal (for example lithium, sodium, potassium, magnesium, calcium and barium salts) and an inorganic acid complex salt, for example, an oxo-anion, such as alkali metal and alkaline-earth metal salts of carbonic acid, such as Na₂CO₃, K₂CO₃, MgCO₃, CaCO₃, and BaCO₃ or fluoro-anion complex such as Li₃AlF₆, BaSiF₆, KBF₄, K₃AlF₆, KAlF₄, K₂SiF₆, and/or Na₃AlF₆ or the like. Rimar salt and KSS and NATS, alone or in combination with other flame retardants, are particularly useful in the compositions disclosed herein. In certain embodiments, the flame retardant does not contain bromine or chlorine.

The flame retardant additives may include organic compounds that include phosphorus, bromine, and/or chlorine. In certain embodiments, the flame retardant is not a bromine or chlorine containing composition. Non-brominated and non-chlorinated phosphorus-containing flame retardants can include, for example, organic phosphates and organic compounds containing phosphorus-nitrogen bonds. Exemplary di- or polyfunctional aromatic phosphorus-containing compounds include resorcinol tetraphenyl diphosphate (RDP), the bis(diphenyl)phosphate of hydroquinone and the bis(diphenyl)phosphate of bisphenol-A, respectively, their oligomeric and polymeric counterparts, and the like. Other exemplary phosphorus-containing flame retardant additives include phosphonitrilic chloride, phosphorus ester amides, phosphoric acid amides, phosphonic acid amides, phosphinic acid amides, tris(aziridinyl)phosphine oxide, polyorganophosphazenes, and polyorganophosphonates.

Exemplary antioxidant additives include organophosphites such as tris(nonyl phenyl)phosphite, tris(2,4-di-t-butylphenyl)phosphite (“IRGAFOS 168” or “I-168”), bis(2,4-di-t-butylphenyl)pentaerythritol diphosphite, distearyl pentaerythritol diphosphite or the like; alkylated monophenols or polyphenols; alkylated reaction products of polyphenols with dienes, such as tetrakis[methylene(3,5-di-tert-butyl-4-hydroxyhydrocinnamate)]methane, or the like; butylated reaction products of para-cresol or dicyclopentadiene; alkylated hydroquinones; hydroxylated thiodiphenyl ethers; alkylidene-bisphenols; benzyl compounds; esters of beta-(3,5-di-tert-butyl-4-hydroxyphenyl)-propionic acid with monohydric or polyhydric alcohols; esters of beta-(5-tert-butyl-4-hydroxy-3-methylphenyl)-propionic acid with monohydric or polyhydric alcohols; esters of thioalkyl or thioaryl compounds such as distearylthiopropionate, dilaurylthiopropionate, ditridecylthiodipropionate, octadecyl-3-(3,5-di-tert-butyl-4-hydroxyphenyl)propionate, pentaerythrityl-tetrakis[3-(3,5-di-tert-butyl-4-hydroxyphenyl)propionate or the like; amides of beta-(3,5-di-tert-butyl-4-hydroxyphenyl)-propionic acid or the like, or combinations comprising at least one of the foregoing antioxidants.

### Methods

The laser platable compositions of the present disclosure can be formed according to a number of methods. The compositions of the present disclosure can be blended, compounded, or otherwise combined with the aforementioned ingredients by a variety of methods involving intimate admixing of the materials with any additional additives desired in the formulation. Because of the availability of melt blending equipment in commercial polymer processing facilities, melt processing methods can be used. In various further aspects, the equipment used in such melt processing methods can include, but is not limited to, the following: co-rotating and counter-rotating extruders, single screw extruders, twin extruders, co-kneaders, disc-pack processors and various other types of extrusion equipment. In one example, the extruder is a twin-screw extruder. In various further examples, the composition can be processed in an extruder at temperatures from 180° C. to 350° C., or from about 180° C. to about 350° C.

### Properties and Articles

The compositions described herein can be used to produce molded, photopermeable articles having a dark color and that are amenable to laser plating processes.

The molded articles can be used in the manufacture of various end use articles and products. Articles that can be manufactured from the compositions of the present disclosure can find extensive use in applications requiring aesthetic versatility without sacrificing mechanical properties or laser platability, that is, the extent to which laser plating can be achieved.

In certain aspects of the present disclosure, the compositions disclosed herein may exhibit a significant change in transmittance between the UV-visible (UV-vis) range and longer wavelengths, such as those corresponding to near infrared and longer. That is, in various aspects, the compositions may exhibit a change in transmittance of at least 10%, or at least about 10%, between a transmittance observed between 190 nm and 400 nm and a transmittance observed from 700 nm to 2500 nm. That is, in various aspects, the compositions may exhibit a change in transmittance of at least 20%, or at least about 20%, between a transmittance observed between 190 nm and 400 nm and a transmittance observed from 700 nm to 2500 nm. Further, the compositions may exhibit a change in transmittance of at least 30%, or at least about 30%, between a transmittance observed between 190 nm and 400 nm and a transmittance observed from 700 nm to 2500 nm. For example, the composition may exhibit a percent transmittance of up to about 20% at a wavelength from about 190 nm to about 400 nm and a transmittance of greater than 40% at a wavelength from about 700 nm to about 2500 nm.

In various aspects, the disclosed compositions can utilize the advantage of laser plating additives to achieve selective metallic, as well as conductive, pathways on even resin surfaces as well as irregular surfaces, soft surfaces, layered surfaces, or other surfaces that may not be readily plated otherwise. For example, with the disclosed compositions, laser irradiation can provide a means of generating circuitry or antennae on the surface of a thermoplastic resin substrate. Thus the disclosed compositions can be appropriate for articles in the electrical and electronics field. The compositions can provide desirable dark colored resins that are suitable for molding and are also amenable to laser plating. Unlike compositions comprising non-photopermeable colorants, the disclosed compositions can feature the desired deep hues and undergo laser plating without exhibiting the damage to the resin surface which a non-photopermeable colorant composition would exhibit under comparable laser irradiation intensity and frequencies. As such, the dark colored compositions disclosed herein can be utilized for laser plating processes without the concern that the laser irradiation used will damage the substrate resin composition.

The present disclosure pertains to and includes at least the following aspects.

Aspect 1. A composition comprising: from 10 wt. % to 90 wt. %, or from about 10 wt. % to about 90 wt. %, of a polymer base resin; from 0.1 wt. % to 60 wt. %, or from about 0.1 wt. % to about 60 wt. %, of a reinforcing filler; from 0.1 wt. % to 10 wt. %, or from about to about 10 wt. %, of a laser direct structuring additive; and from 0.01 wt. % to 10 wt. %, or from about 0.01 wt. % to about 10 wt. %, of a photopermeable colorant, wherein the combined weight percent value of all components does not exceed 100 wt. %, and wherein all weight percent values are based on the total weight of the composition, wherein the composition exhibits a transmittance of up to 20%, or up to about 20 wt. %, at from 190 nm to 400 nm and a transmittance of greater than 50%, or greater than about 50%, at from 700 nm to 2500 nm; and wherein the composition is configured to be activated by laser.

Aspect 2. A composition consisting essentially of: from 10 wt. % to 90 wt. %, from about 10 wt. % to about 90 wt. %, of a polymer base resin; from 0.1 wt. % to 60 wt. % of a reinforcing filler or from about 0.1 wt. % to about 60 wt. %; from 0.1 wt. % to 10 wt. % or from about to about 10 wt. % of a laser direct structuring additive; and from 0.01 wt. % to 10 wt. %, or from about 0.01 wt. % to about 10 wt. %, of a photopermeable colorant, wherein the combined weight percent value of all components does not exceed 100 wt. %, and wherein all weight percent values are based on the total weight of the composition, wherein the composition exhibits a transmittance of up to 20% at from 190 nm to 400 nm and a transmittance of greater than 50% at from 700 nm to 2500 nm; and wherein the composition is configured to be activated by laser.

Aspect 3. A composition consisting of: from 10 wt. % to 90 wt. %, from about 10 wt. % to about 90 wt. %, of a polymer base resin; from 0.1 wt. % to 60 wt. % of a reinforcing filler or from about 0.1 wt. % to about 60 wt. %; from 0.1 wt. % to 10 wt. % or from about 0.01 wt. % to about 10 wt. % of a laser direct structuring additive; and from 0.01 wt. % to 10 wt. %, or from about 0.01 wt. % to about 10 wt. %, of a photopermeable colorant, wherein the combined weight percent value of all components does not exceed 100 wt. %, and wherein all weight percent values are based on the total weight of the composition, wherein the composition exhibits a transmittance of up to 20% at from 190 nm to 400 nm and a transmittance of greater than 50% at from 700 nm to 2500 nm; and wherein the composition is configured to be activated by laser.

Aspect 4. A composition comprising: from 10 wt. % to 65 wt. %, or from about 10 wt. % to about 65 wt. %, of a polymer base resin; from 0.1 wt. % to 40 wt. %, or from about 0.1 wt. % to about 40 wt. %, of a reinforcing filler; from 0.1 wt. % to 8 wt. %, or from about 0.01 wt. % to about 8 wt. %, of a laser direct structuring additive; and from 0.01 wt. % to 5 wt. %, or from about 0.01 wt. % to about 5 wt. %, of a photopermeable colorant, wherein the combined weight percent value of all components does not exceed 100 wt. %, and wherein all weight percent values are based on the total weight of the composition, wherein the composition exhibits a transmittance of up to 20%, or up to about 20 wt. %, at from 190 nm to 400 nm and a transmittance of greater than 50%, or greater than about 50%, at from 700 nm to 2500 nm; and wherein the composition is configured to be activated by laser.

Aspect 5. A composition comprising: from 10 wt. % to 90 wt. %, from about 10 wt. % to about 90 wt. %, of a polymer base resin; from 0.1 wt. % to 60 wt. % of a reinforcing filler or from about 0.1 wt. % to about 60 wt. %; from 0.1 wt. % to 10 wt. % or from about 0.01 wt. % to about 10 wt. % of a laser direct structuring additive; and from 0.01 wt. % to 10 wt. %, or from about 0.01 wt. % to about 10 wt. %, of a photopermeable colorant, wherein the combined weight percent value of all components does not exceed 100 wt. %, and wherein all weight percent values are based on the total weight of the composition, wherein the composition exhibits a change in transmittance of at least 20% between a transmittance observed between 190 nm and 400 nm and a transmittance observed from 700 nm to 2500 nm; and wherein the composition is configured to be activated by laser.

Aspect 6. A composition consisting essentially of: from 10 wt. % to 90 wt. %, from about 10 wt. % to about 90 wt. %, of a polymer base resin; from 0.1 wt. % to 60 wt. % of a reinforcing filler or from about 0.1 wt. % to about 60 wt. %; from 0.1 wt. % to 10 wt. % or from about 0.01 wt. % to about 10 wt. % of a laser direct structuring additive; and from 0.01 wt. % to 10 wt. %, or from about 0.01 wt. % to about 10 wt. %, of a photopermeable colorant, wherein the combined weight percent value of all components does not exceed 100 wt. %, and wherein all weight percent values are based on the total weight of the composition, wherein the composition exhibits a change in transmittance of at least 20% between a transmittance observed between 190 nm and 400 nm and a transmittance observed from 700 nm to 2500 nm; and wherein the composition is configured to be activated by laser.

Aspect 7. A composition consisting of: from 10 wt. % to 90 wt. %, from about 10 wt. % to about 90 wt. %, of a polymer base resin; from 0.1 wt. % to 60 wt. % of a reinforcing filler or from about 0.1 wt. % to about 60 wt. %; from 0.1 wt. % to 10 wt. % or from about 0.01 wt. % to about 10 wt. % of a laser direct structuring additive; and from 0.01 wt. % to 10 wt. %, or from about 0.01 wt. % to about 10 wt. %, of a photopermeable colorant, wherein the combined weight percent value of all components does not exceed 100 wt. %, and wherein all weight percent values are based on the total weight of the composition, wherein the composition exhibits a change in transmittance of at least 20% between a transmittance observed between 190 nm and 400 nm and a transmittance observed from 700 nm to 2500 nm; and wherein the composition is configured to be activated by laser.

Aspect 8. The composition of any of claims 1-7, wherein the laser activated composition is configured to be metal plated.

Aspect 9. The composition of claim 8, wherein the metal plated composition exhibits an average Plating Index at less than 10%, or less than about 10%, difference from a Plating Index of a substantially similar metal plated composition in the absence of a photopermeable colorant when measured at the same laser intensities.

Aspect 10. The composition of claim 8, wherein the metal plated composition exhibits an average Plating Index at less than 5%, or less than about 5%, difference from a Plating Index of a substantially similar metal plated composition in the absence of a photopermeable colorant when measured at the same laser intensities.

Aspect 11. The composition of any one of claims 1-10, wherein the composition is activated by laser at 1064 nm.

Aspect 12. The composition of any one of claims 1-10, wherein an amount of the photopermeable colorant is configured such that the composition has a transmittance of below 20% at from 190 nm to 400 nm.

Aspect 13. The composition of any one of claims 1-10, wherein the loading of the photopermeable colorant is configured such that the composition has a transmittance of below 20% at from 190 nm to 400 nm and wherein the composition is subjected to laser irradiation at wavelengths of from 700 nm to 2500 nm without exhibiting damage to an irradiated surface of the composition when compared to a substantially similar composition excluding the photopermeable colorant but comprising a non-photopermeable colorants instead of photopermeable colorants under comparable laser irradiation intensity and frequencies.

Aspect 14. The composition of any one of claims 1-13, wherein the polymer base resin comprises polypropylene, polyethylene, ethylene based copolymer, polycarbonate, polyamide, polyester, polyoxymethylene, polybutylene terephthalate, polyethylene terephthalate, polycyclohexylendimethylene terephthalate, liquid crystal polymers, polyphenylene Sulfide, polyphenylene ether, polyphenylene oxide-polystyrene blends, polystyrene, high impact modified polystyrene, acrylonitrile-butadiene-styrene terpolymer, acrylic polymer, polyetherimide, polyurethane, polyetheretherketone, poly ether sulphone, or a combination thereof.

Aspect 15. The composition of any one of claims 1-14, wherein the polymer base resin comprises a polycarbonate having units derived from bisphenol A or a poly(aliphatic ester)-polycarbonate copolymer, or a combination thereof.

Aspect 16. The composition of any one of claims 1-15, wherein the reinforcing filler comprises glass fiber, carbon fiber, a mineral filler, or a combination thereof.

Aspect 17. The composition of any one of claims 1-15, wherein the reinforcing filler comprises flat glass fiber.

Aspect 18. The composition of any one of claims 1-17, wherein the laser direct structuring additive comprises a heavy metal mixture oxide spinel, such as copper chromium oxide spinel; a copper salt, such as copper hydroxide phosphate copper phosphate, copper sulfate, cuprous thiocyanate, spinel based metal oxides (such as copper chromium oxide), organic metal complexes (such as palladium/palladium-containing heavy metal complexes), metal oxides, metal oxide-coated fillers, antimony doped tin oxide coated on a mica substrate, a copper containing metal oxide, a zinc containing metal oxide, a tin containing metal oxide, a magnesium containing metal oxide, an aluminum containing metal oxide, a gold containing metal oxide, a silver containing metal oxide, or the like; or a combination including at least one of the foregoing LDS additives.

Aspect 19. The composition of any one of claims 1-8, wherein the photopermeable colorant comprises solvent red, solvent blue, solvent green, or disperse yellow, or some combination thereof.

Aspect 20. The composition of any one of claims 1-19, wherein the photopermeable colorant does not absorb light at wavelengths longer than 600 nm.

Aspect 21. The composition of any of claims 1-20, wherein the photopermeable colorant does not absorb light at wavelengths longer than 700 nm.

Aspect 22. The composition of any one of claims 1-21, further comprising an additive.

Aspect 23. The composition of claim 22, wherein the additive comprises ultraviolet agents, ultraviolet stabilizers, heat stabilizers, antistatic agents, anti-microbial agents, impact modifiers, anti-drip agents, radiation stabilizers, pigments, dyes, fibers, fillers, plasticizers, fibers, flame retardants, antioxidants, lubricants, wood, glass, and metals, and combinations thereof.

Aspect 24. The composition of any one of claims 22-23, wherein the additive comprises an acrylic impact modifier comprising an ethylene-ethylacrylate copolymer.

Aspect 25. A molded article formed according to the composition of any of claims 1-24.

Aspect 26. A method of forming a composition comprising: from 10 wt. % to 90 wt. %, from about 10 wt. % to about 90 wt. %, of a polymer base resin; from 0.1 wt. % to 60 wt. % of a reinforcing filler or from about 0.1 wt. % to about 60 wt. %; from 0.1 wt. % to 10 wt. % or from about to about 10 wt. % of a laser direct structuring additive; and from 0.01 wt. % to 10 wt. %, or from about 0.01 wt. % to about 10 wt. %, of a photopermeable colorant, wherein the combined weight percent value of all components does not exceed about 100 wt. %, and wherein all weight percent values are based on the total weight of the composition, wherein the composition exhibits a percent transmittance of up to about 20% at from about 190 nm to about 400 nm and a percent transmittance of greater than 50% at from about 700 nm to about 2500 nm; wherein the composition is configured to be metal plated; and wherein the metal plated composition exhibits an average Plating Index at less than 10% difference from a Plating Index of a substantially similar metal plated composition in the absence of a photopermeable colorant when measured at the same laser intensities.

Aspect 27. A molded article comprising: from about 10 wt. % to about 90 wt. % of a polymer base resin; from about 0.1 wt. % to about 60 wt. % of a reinforcing filler; from about 0.1 wt. % to about 10 wt. % of a laser direct structuring additive; and from about 0.01 wt. % to about 10 wt. % of a photopermeable colorant, wherein the combined weight percent value of all components does not exceed about 100 wt. %, and wherein all weight percent values are based on the total weight of the composition, wherein the composition exhibits a percent transmittance of up to about 20% at from about 190 nm to about 400 nm and a percent transmittance of greater than 50% at from about 700 nm to about 2500 nm; wherein the composition is configured to be metal plated; and wherein the metal plated composition exhibits an average Plating Index at less than 10% difference from a Plating Index of a substantially similar metal plated composition in the absence of a photopermeable colorant when measured at the same laser intensities.

Aspect 28. A method of forming a composition comprising: from about 10 wt. % to about 90 wt. % of a polymer base resin; from about 0.1 wt. % to about 60 wt. % of a reinforcing filler; from about 0.1 wt. % to about 10 wt. % of a laser direct structuring additive; and from about 0.01 wt. % to about 10 wt. % of a photopermeable colorant, wherein the combined weight percent value of all components does not exceed about 100 wt. %, and wherein all weight percent values are based on the total weight of the composition, wherein the composition exhibits a percent transmittance of up to about 20% at from about 190 nm to about 400 nm and a percent transmittance of greater than 50% at from about 700 nm to about 2500 nm; wherein the composition is configured to be metal plated; and wherein the metal plated composition exhibits an average Plating Index at less than 10% difference from a Plating Index of a substantially similar metal plated composition in the absence of a photopermeable colorant when measured at the same laser intensities.

### EXAMPLES

Detailed embodiments of the present disclosure are disclosed herein; it is to be understood that the disclosed embodiments are merely exemplary of the disclosure that may be embodied in various forms. Therefore, specific structural and functional details disclosed herein are not to be interpreted as limits, but merely as a basis for teaching one skilled in the art to employ the present disclosure. The specific examples below will enable the disclosure to be better understood. However, they are given merely by way of guidance and do not imply any limitation.

The following examples are provided to illustrate the compositions, processes, and properties of the present disclosure. The examples are merely illustrative and are not intended to limit the disclosure to the materials, conditions, or process parameters set forth therein.

### General Materials and Methods

The compositions as set forth in the Examples below were prepared from the components presented in Table 1.

TABLE 1
Components of the thermoplastic compositions.

| Item Code | Item Description |
|---|---|
| C914090 | Sebacic acid/BPA/PCP polyestercarbonate |
| C914089 | Sebacic Acid/BPA copolymer |
| C893696 | Branched THPE, HBN Endcapped PC |
| F538 | Pentaerythritol tetrastearate (PETS) |
| F527 | Hindered phenol antioxidant |
| F542 | Phosphite stabilizer |
| F232 | Acrylic polymer impact modifier |
| F722236 | Joncryl ™ ADR 4368CS |
| F4520 | Phosphorous acid 45% |
| F8260 | Mono zinc phosphate (MZP) |
| G512972 | Nittobo, CSG 3PA-830, flat fiber |
| F593895 | Lazerflair ™ 8840 (Article number 1.41055; |
| | Cu₃(PO₄)₂Cu(OH)₂) |
| R203 | Carbon black pigment; medium color powder |
| R665 | Solvent red 135 |
| R32P | Solvent green 3 |

The colorant carbon black and photopermeable colorants are presented in further detail in Table 2.

TABLE 2
Resin colorants.

| Item | Trade Name | | Chemical | |
|---|---|---|---|---|
| Code | (Supplier) | CAS # | Name | Chemical Structure |
| R203 | Carbon Black | 1333-86-4 | Carbon | C |
| | (CABOT) | | Black | |
| R665 | MACROLEX ™ Red EG Granulate (LANXESS) | 71902-17-5 | Solvent Red 135 | 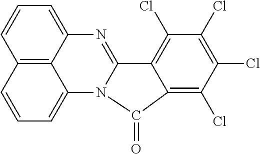 [SMILES: O=C1c2c(Cl)c(Cl)c(Cl)c(Cl)c2C2=Nc3cccc4cccc(c34)N12] |
| R32P | MACROLEX ™ Green 5B (LANXESS) | 128-80-3 | Solvent Green 3 | 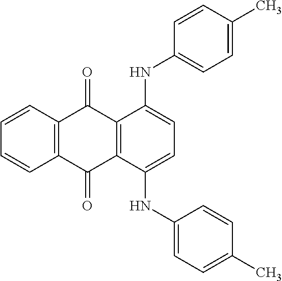 |
| R885 | MACROLEX ™ Yellow 6G Granulate (LANXESS) | 80748-21-6 | Disperse Yellow 201 | 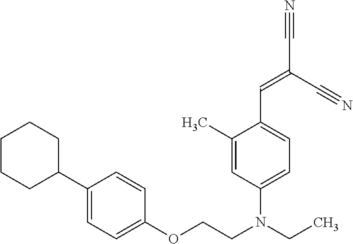 [SMILES: CCN(CCOc1ccc(C2CCCCC2)cc1)c1ccc(C=C(C#N)C#N)c(C)c1] |
| R75 | Sandoplast Blue 2B p (Clariant) | 116-75-6 | Solvent Blue 104 | 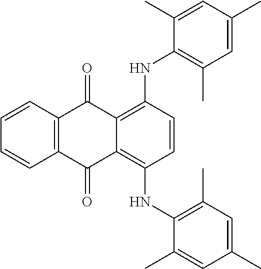 |

Thermoplastic resin compositions were prepared by combining selected components as presented in Table 1. The thermoplastic resins were formed by compounding selected components in a 7 mm Toshiba™ SE twin screw extruder. The colorants were pre-blended with the polymer base resin and additives before feeding from the main throat. Additional fiber fillers were fed from downstream to provide pellets. The pellets were then dried to provide the compositions of the present disclosure. The parameters for extrusion are presented in Table 3. Molecular weight, rheological performance, and optical properties were determined using the pelletized composition.

TABLE 3
Extrusion parameters

| Parameters | Unit | Resin |
|---|---|---|
| Compounder Type | NONE | TEM-37BS |
| Barrel Size | mm | 1500 |
| Die | mm | 3 |
| Feed (Zone 0) Temp | NONE | 50 |
| Zone 1 Temp | ° C. | 100 |
| Zone 2 Temp | ° C. | 150 |
| Zone 3 Temp | ° C. | 200 |
| Zone 4 Temp | ° C. | 255 |
| Zone 5 Temp | ° C. | 255 |
| Zone 6 Temp | ° C. | 255 |
| Zone 7 Temp | ° C. | 255 |
| Zone 8 Temp | ° C. | 255 |
| Zone 9 Temp | ° C. | 260 |
| Zone 10 Temp | ° C. | 260 |
| Zone 11 Temp | ° C. | 260 |
| Die Temp | ° C. | 265 |
| Screw speed | rpm | 300 |
| Throughput | kg/hr | 40 |
| Torque | NONE | 70 |
| Vacuum 1 | MPa | −0.08 |
| Side Feeder 1 speed | rpm | >200 |
| Melt temperature | NONE | 275 |

The compositions were molded for the assessment of mechanical strength and LDS properties. The molding profile is presented in Table 4.

TABLE 4
Molding profile.

| Parameters | Unit | Resin |
|---|---|---|
| Cnd: Pre-drying time | Hour | 3 |
| Cnd: Pre-drying temp | ° C. | 110 |
| Molding Machine | NONE | FANUC |
| Mold Type (insert) | NONE | ASTM |
| Hopper temp | ° C. | 50 |
| Zone 1 temp | ° C. | 270-280 |
| Zone 2 temp | ° C. | 275-285 |
| Zone 3 temp | ° C. | 280-290 |
| Nozzle temp | ° C. | 275-285 |
| Mold temp | ° C. | 80-120 |
| Screw speed | rpm | 100 |
| Back pressure | kilogram force per square | 30-50 |
| | centimeter (kgf/cm²) | |
| Cooling time | Seconds (s) | 15 |
| Injection speed | mm/s | 50-150 |
| Holding pressure | kgf/cm² | 600-800 |
| Max. Injection pressure | kgf/cm² | 1000-1200 |

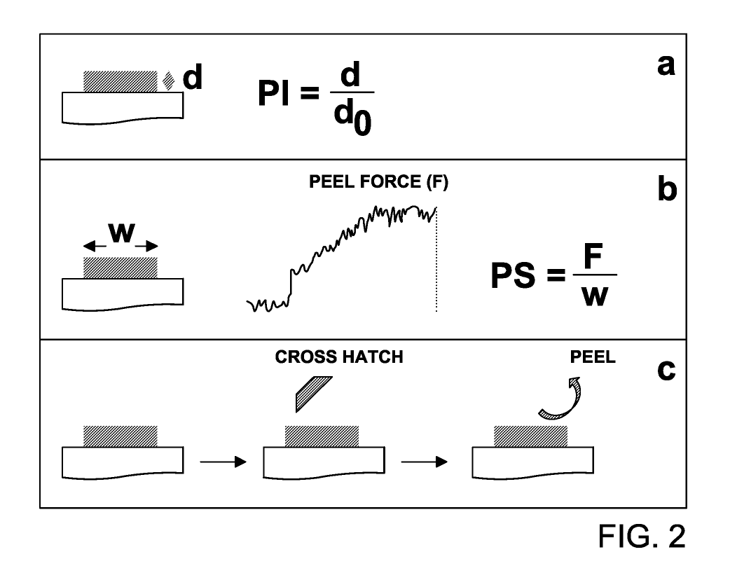

LDS performance was observed according to three parameters: plating index (PI), peel strength (PS), and cross hatch (CH). After the resin sample has been plated with a metal, PI is a measure of the metal thickness using X-ray fluorescence methodology. PI was observed with a Fischer™ XDL230 instrument. Both Peel strength (PS) and cross hatch indicate the bonding strength between a metal and plastic. PS is a quantitative index, while cross hatch is qualitative. For PS, a SANS™ CMT4504 was used to assess the peeling force and for Cross hatch, 3M 610 tape was used. FIG. 2 provides a graphical illustration of the LDS test parameters where d refers to the thickness of the metal as plated on a resin sample surface, d₀ refers to the thickness of the metal as plated on a control sample surface, and w refers to the width of the metal as plated on a sample surface.

A control sample (CS) and an example (E1) of the thermoplastic resin comprising photopermeable colorants were prepared as set forth in Table 5.

TABLE 5
Formulations of control and example.

| Item Code | Item Description | Unit | CS | E1 |
|---|---|---|---|---|
| C914090 | Sebacic acid/BPA/PCP polyester- | % | 14.3 | 14.3 |
| | carbonate | | | |
| C914089 | Sebacic Acid/BPA copolymer | % | 34.59 | 34.59 |
| C893696 | Branched THPE, HBN Endcapped PC | % | 10 | 10 |
| F538 | Pentaerythritol tetrastearate (PETS) | % | 0.5 | 0.5 |
| F527 | Hindered phenol antioxidant | % | 0.1 | 0.1 |
| F542 | Phosphite stabilizer | % | 0.1 | 0.1 |
| F232 | Acrylic polymer impact modifier | % | 5 | 5 |
| F722236 | Joncryl ™ ADR 4368CS | % | 0.1 | 0.1 |
| F4520 | Phosphorous acid 45% | % | 0.01 | 0.01 |
| F8260 | Mono zinc phosphate (MZP) | % | 0.3 | 0.3 |
| G512972 | Nittobo, CSG 3PA-830, flat fiber | % | 30 | 30 |
| F593895 | Lazerflair ™ 8840 (Article number | % | 5 | 5 |
| | 1.41055) | | | |
| R203 | Carbon black pigment; medium color | % | 0.3 | 0 |
| | powder | | | |
| R665 | Solvent red 135 | % | 0 | 0.3 |
| R32P | Solvent green 3 | % | 0 | 0.3 |

As noted herein, optical, mechanical and laser direct structuring properties were observed for CS and E1. Optical properties were observed by UV-VIS (UV-visible) absorption measurements. As provided herein, the optical absorption property of each colorant is shown in FIG. 1. An amount 0.02 grams of each colorant was dispersed in 20 milliliters (ml) of chloroform and measured in transmission mode by UV-VIS. Carbon black (R203) showed continuous function of transmittance curve across all wavelength, and the transmittance value is below 20% at all wavelength. The measurements are consistent with the strong light absorption of carbon black at all wavelength ranges. The other colorants, namely R665, R32P, R885, R75, exhibited discontinuous function of transmittance curve. Each colorant has characteristic peaks within UV-VIS range, which relate to their color performance visually. Each has high transmittance at NIR range. For example, R665, R32P, R885, R75 exhibit nearly 100% transmittance at greater than 700 nm wavelength. At the laser wavelength of LDS, only carbon black R203 has low transmittance at about 10%, while R665, R32P, R885, R75 all have higher transmittance (about 100% for R665, R32P, R885, R75).” These colorants are thus photopermeable in that they exhibit color, but do not hinder the transmission of light beyond the UV-VIS and NIR ranges, that is, at greater than 700 nm.

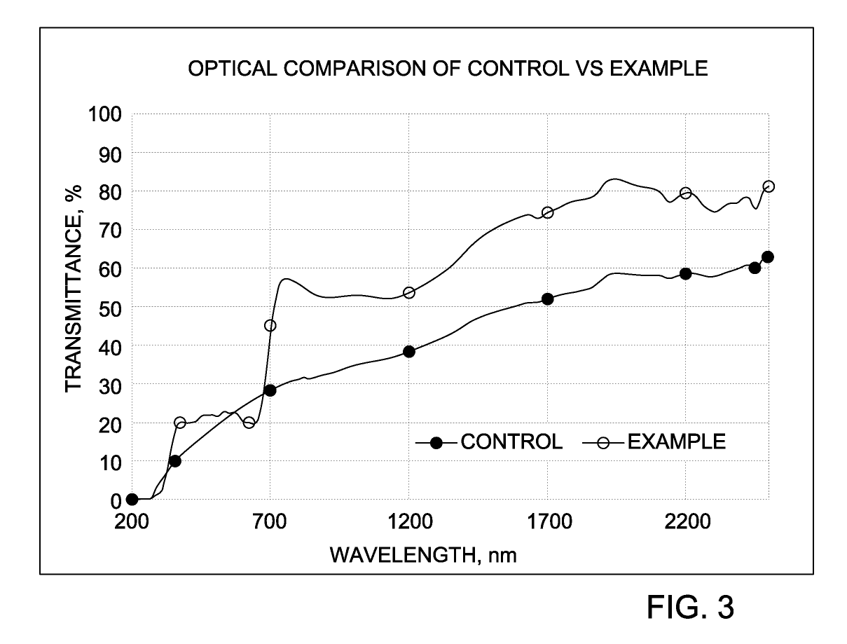

Resin pellets of CS and of E1 were pressed into 15 μm thick films for testing in UV-VIS transmission mode. Samples were evaluated according to the percent of transmittance. A comparison of optical properties of CS and E1 is presented in FIG. 3. As shown in FIG. 3, E1 exhibited a percent transmittance of greater than 50% at wavelengths above 700 nm while CS1 (containing carbon black) did not exhibit a transmittance of greater than 50% until about 1600 nm. The greater wavelength indicated that CS1 continued to absorb light at wavelengths well beyond the UV-VIS and also near infrared (IR) ranges.

The mechanical and physical properties for CS and E1 were evaluated according to the testing parameters as follows. The results for mechanical and physical properties are presented in Table 6. Melt volume—flow rate (“MFR”) was determined according to standard ASTM D1238 (2013) under the following test conditions: 300° C./1.2 kg load/300 second dwell time. Data below are provided for MFR in grams per 10 minutes (g/10 min). Heat deflection temperature (“HDT”) was determined per ASTM D648 (2007) with flatwise specimen orientation with a 3.2 mm specimen at 0.45 megaPascals (MPa). Data are provided below in units of ° C. Flexural properties (modulus and strength) were determined according to ASTM D790 (2010). Data below are provided in MPa. Tensile properties were measured in accordance with ASTM D638 (2010). Tensile strength and elongation at break are reported in units of MPa and % elongation, respectively. The notched Izod impact (“NII”) and unnotched Izod impact tests were carried out according to ASTM D256 (2010) at 23° C. for 2 pound force per foot (lbf/ft). Data units are joules per meter (Jim). The dielectric constant (Dk) and dissipation factor (DO were also evaluated at 1.1 gigahertz (GHz). Values for Dk and Df were obtained using a QWED split post dielectric resonator and Agilent network analyzer. For 1.1 GHz measurement, the minimum sample size was 120 mm by 120 mm and the maximum sample thickness was 6 mm. An injection molded sample had a size of 150 mm by 150 mm by 1.5 mm.

TABLE 6
Properties of CS and E1.

| Typical Property | Unit | Control | Example |
|---|---|---|---|
| MFR | g/10 min | 14 | 15 |
| HDT | ° C. | 125 | 125 |
| Flexural Modulus | MPa | 7870 | 7500 |
| Flexural Strength | MPa | 167 | 163 |
| Tensile Modulus | MPa | 9083 | 9235 |
| Tensile Strength | MPa | 113 | 118 |
| Tensile Elongation | % elong. | 2.2 | 2.1 |
| Notched Izod | J/m | 125 | 136 |
| Unnotched IZOD | J/m | 582 | 629 |
| Dk | — | 3.540 | 3.510 |
| Df | — | 0.013 | 0.013 |

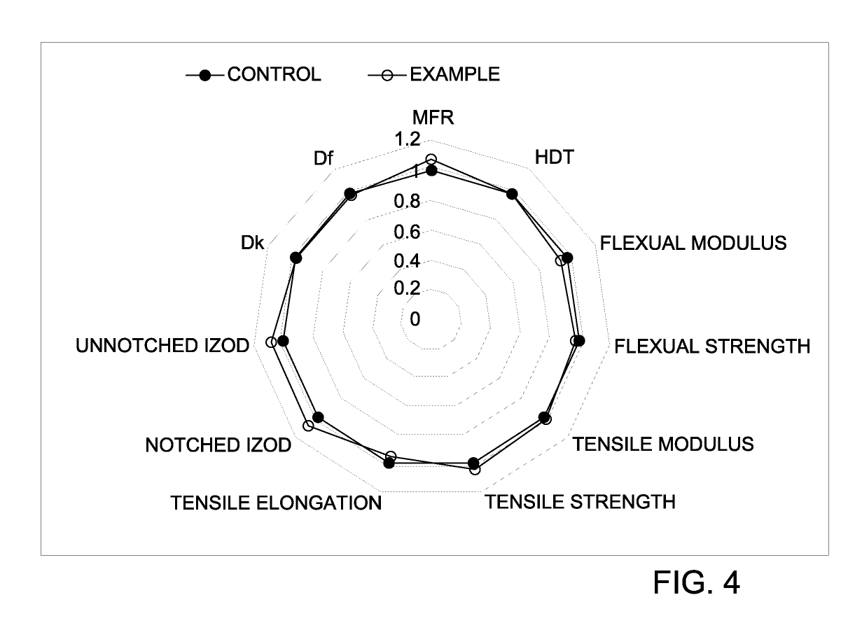

FIG. 4 provides a radar comparison of the mechanical properties of CS and E1. As shown in the figure, the properties of E1 do not appear to significantly depart from those of CS. Indeed, for certain properties, E1 exhibited an improvement (see MFR, tensile modulus, tensile strength, and notched and unnotched Izod impact strength). These results indicate that the integrity of the composition can be maintained, and in certain areas, improved with the incorporation of a photopermeable colorant instead of carbon black.

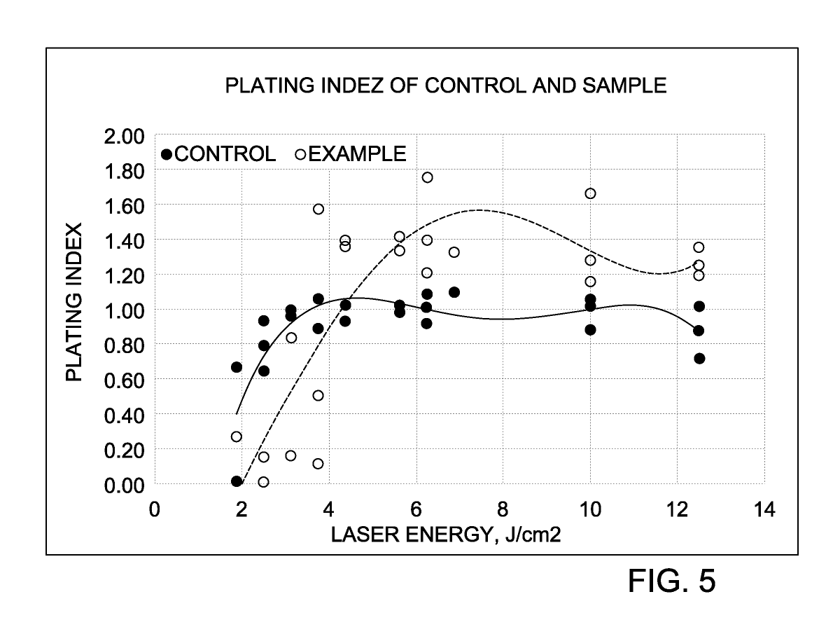

With respect to the LDS performance, the plating index is presented in Table 7. As shown, CS and E1 do not differ significantly (greater than 10% difference). It is noted that CS and E1 do perform differently according to the laser power (watts, W), laser frequency (kilohertz, kHz), and speed (meter per second, m/s). Nevertheless, the percent difference in total average is less than 5%. Regarding LDS performance, plating indices as provided in Table 7 are also presented graphically in FIG. 5 for CS1 and E1.

TABLE 7
Plating index and percent difference between CS and E1

| Power, W | Frequency, | Speed, m/s | Control | Example |
|---|---|---|---|---|
| 10 | 100 | 2 | 0.72 | 1.20 |
| 10 | 70 | 2 | 0.87 | 1.25 |
| 10 | 40 | 2 | 1.02 | 1.35 |
| 2 | 100 | 2 | 0.64 | 0.00 |
| 2 | 70 | 2 | 0.93 | 0.01 |
| 2 | 40 | 2 | 0.79 | 0.15 |
| 7 | 80 | 4 | 0.93 | 1.39 |
| 5 | 80 | 4 | 0.96 | 0.83 |
| 3 | 80 | 4 | 0.67 | 0.27 |
| 3 | 100 | 2 | 1.06 | 0.12 |
| 3 | 70 | 2 | 1.06 | 0.50 |
| 3 | 40 | 2 | 0.89 | 1.57 |
| 5 | 100 | 4 | 0.99 | 0.16 |
| 3 | 100 | 4 | 0.01 | 0.00 |
| 9 | 80 | 4 | 0.99 | 1.41 |
| 5 | 100 | 2 | 1.01 | 1.21 |
| 5 | 70 | 2 | 1.08 | 1.40 |
| 5 | 40 | 2 | 0.92 | 1.75 |
| 11 | 100 | 4 | 1.09 | 1.32 |
| 9 | 100 | 4 | 1.02 | 1.34 |
| 7 | 100 | 4 | 1.02 | 1.36 |
| 8 | 100 | 2 | 0.89 | 1.15 |
| 8 | 70 | 2 | 1.05 | 1.28 |
| 8 | 40 | 2 | 1.01 | 1.66 |

| | | |
|---|---|---|
| Average | 0.90 | 0.94 |

| | |
|---|---|
| Percent difference in average | 4.44% |

Cross hatch results were also evaluated. Four series of six cross hatch experiments were performed. Darker regions of the cross hatching array indicated peeling off (or separation of) the metal from the resin at a given laser intensity. The power of the laser used was varied from 3 Watts to 11 Watts, the laser frequency varied from 40 kHz to 100 kHz, and the laser scan speed maintained at 2 m/s. The first and second series correspond to varied laser power applied at 100 kHz and 40 kHz, respectively, for CS1. CS1 exhibited more dark areas corresponding to peeling at 100 kHz frequency at all power levels. A second series of cross hatch showed less peeling off at 40 kHz frequency and all power levels for CS1. However, series corresponding to E1 did not show an increase in dark regions, thus there was less peeling. Combining these cross hatch results with the PI values as presented in Table 7, it appears that E1 exhibited better metal bonding strength than CS1 at each laser intensity and frequency, regardless of the metal thickness.

Formulations containing varying amounts of carbon black or photopermeable colorants were compared. Table 8 presents control or comparative formulations without colorant, designated (N), and 0.3% to 2% loadings of carbon black (C1, C2, C3, C4). Table 9 also presents formulations without colorant (N) and 0.3% to 2% loadings of photopermeable colorants (EX1, EX2, EX3, EX4).

TABLE 8
Formulations containing no colorant (N) and varied
loadings of carbon black (C1, C2, C3, C4)

| Item Code | Unit | N | C1 | C2 | C3 | C4 |
|---|---|---|---|---|---|---|
| C914090 | % | 14.3 | 14.3 | 14.3 | 14.3 | 14.3 |
| C914089 | % | 34.59 | 34.59 | 34.59 | 34.59 | 34.59 |
| C893696 | % | 10 | 10 | 10 | 10 | 10 |
| F538 | % | 0.5 | 0.5 | 0.5 | 0.5 | 0.5 |
| F527 | % | 0.1 | 0.1 | 0.1 | 0.1 | 0.1 |
| F542 | % | 0.1 | 0.1 | 0.1 | 0.1 | 0.1 |
| F232 | % | 5 | 5 | 5 | 5 | 5 |
| F722236 | % | 0.1 | 0.1 | 0.1 | 0.1 | 0.1 |
| F4520 | % | 0.01 | 0.01 | 0.01 | 0.01 | 0.01 |
| F8260 | % | 0.3 | 0.3 | 0.3 | 0.3 | 0.3 |
| G512972 | % | 30 | 30 | 30 | 30 | 30 |
| F593895 | % | 5 | 5 | 5 | 5 | 5 |
| R203 | % | | 0.3 | 0.6 | 1 | 2 |

TABLE 9
Formulations containing no colorant (N) and varied loadings
of photopermeable colorant (EX1, EX2, EX3, EX4)

| Item Code | Unit | N | EX1 | EX2 | EX3 | EX4 |
|---|---|---|---|---|---|---|
| C914090 | % | 14.3 | 14.3 | 14.3 | 14.3 | 14.3 |
| C914089 | % | 34.59 | 34.59 | 34.59 | 34.59 | 34.59 |
| C893696 | % | 10 | 10 | 10 | 10 | 10 |
| F538 | % | 0.5 | 0.5 | 0.5 | 0.5 | 0.5 |
| F527 | % | 0.1 | 0.1 | 0.1 | 0.1 | 0.1 |
| F542 | % | 0.1 | 0.1 | 0.1 | 0.1 | 0.1 |
| F232 | % | 5 | 5 | 5 | 5 | 5 |
| F722236 | % | 0.1 | 0.1 | 0.1 | 0.1 | 0.1 |
| F4520 | % | 0.01 | 0.01 | 0.01 | 0.01 | 0.01 |
| F8260 | % | 0.3 | 0.3 | 0.3 | 0.3 | 0.3 |
| G512972 | % | 30 | 30 | 30 | 30 | 30 |
| F593895 | % | 5 | 5 | 5 | 5 | 5 |
| R665 | % | | 0.15 | 0.3 | 0.5 | 1 |
| R32P | % | | 0.15 | 0.3 | 0.5 | 1 |

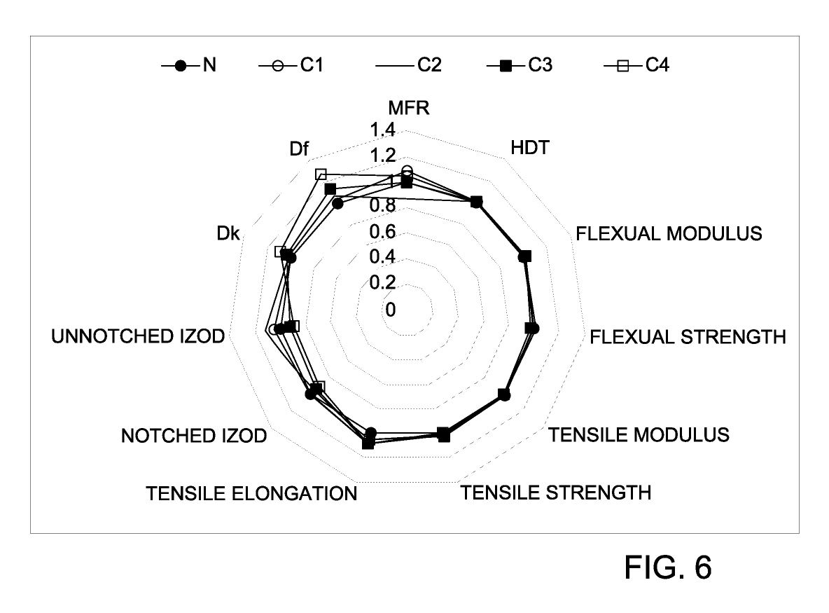

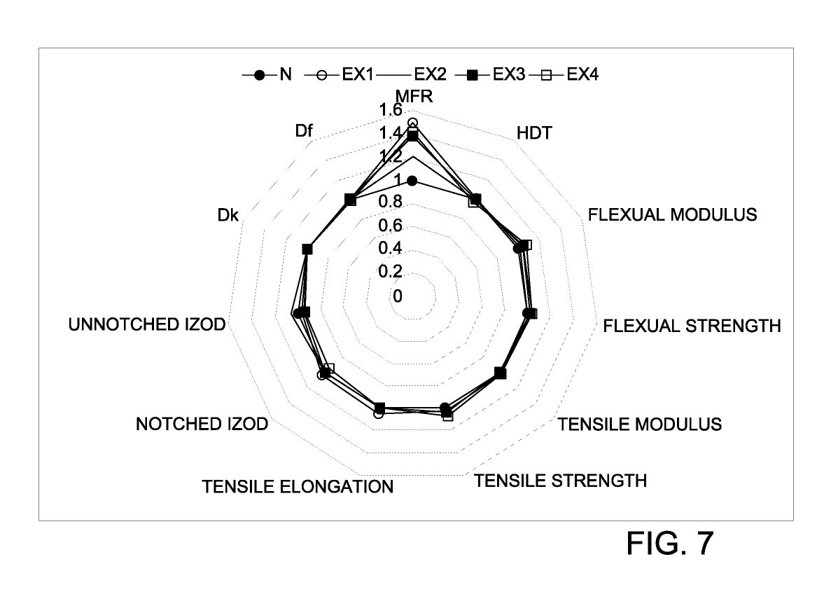

The mechanical and physical properties for formulations were also evaluated and are listed in Table 10 and Table 11 for the control and inventive examples, respectively. Control samples (C1, C2, C3, C4) containing carbon black had very similar properties as compared to the nature color sample (N). This is further supported by radar comparison in FIG. 6. As provided by radar comparison in FIG. 7, the examples (EX1, EX2, EX3, EX4) containing photopermeable colorants had mostly similar properties except an increase in flow (MFR), which was a great benefit as compared to the nature color formulation (N).

TABLE 10
Properties of formulations containing no colorant (N)
and varied loadings of carbon black (C1, C2, C3, C4)

| Typical | | | | | | |
|---|---|---|---|---|---|---|
| Property | Unit | N | C1 | C2 | C3 | C4 |
| MFR | g/10 min | 12 | 13 | 10 | 12 | 13 |
| HDT | ° C. | 126 | 127 | 127 | 127 | 126 |
| Flexural | MPa | 7020 | 7210 | 7100 | 7160 | 7070 |
| Modulus | | | | | | |
| Flexural | MPa | 158 | 152 | 160 | 154 | 160 |
| Strength | | | | | | |
| Tensile | MPa | 8793 | 8799 | 8803 | 8776 | 8782 |
| Modulus | | | | | | |
| Tensile | MPa | 106 | 108 | 108 | 108 | 106 |
| Strength | | | | | | |
| Tensile | % | 2.2 | 2.3 | 2.3 | 2.4 | 2.4 |
| Elongation | | | | | | |
| Notched | J/m | 134 | 135 | 129 | 126 | 122 |
| IZOD | | | | | | |
| Unnotched | J/m | 538 | 566 | 605 | 496 | 482 |
| IZOD | | | | | | |
| Dk | | 3.557 | 3.587 | 3.627 | 3.700 | 3.883 |
| Df | | 0.013 | 0.013 | 0.014 | 0.014 | 0.016 |

TABLE 11
Properties of formulations containing no colorant (N) and varied
loadings of photopermeable colorant (EX1, EX2, EX3, EX4)

| Typical | | | | | | |
|---|---|---|---|---|---|---|
| Property | Unit | N | EX1 | EX2 | EX3 | EX4 |
| MFR | g/10 min | 12 | 18 | 14 | 16 | 17 |
| HDT | ° C. | 126 | 126 | 125 | 124 | 122 |
| Flexural | MPa | 7020 | 7120 | 7350 | 7290 | 7530 |
| Modulus | | | | | | |
| Flexural | MPa | 158 | 156 | 163 | 162 | 164 |
| Strength | | | | | | |
| Tensile | MPa | 8793 | 8793 | 8713 | 8757 | 8860 |
| Modulus | | | | | | |
| Tensile | MPa | 106 | 110 | 109 | 110 | 113 |
| Strength | | | | | | |
| Tensile | % | 2.2 | 2.3 | 2.2 | 2.2 | 2.2 |
| Elongation | | | | | | |
| Notched | J/m | 134 | 138 | 134 | 134 | 127 |
| IZOD | | | | | | |
| Unnotched | J/m | 538 | 519 | 568 | 508 | 505 |
| IZOD | | | | | | |
| Dk | | 3.557 | 3.560 | 3.560 | 3.557 | 3.553 |
| Df | | 0.013 | 0.013 | 0.013 | 0.013 | 0.013 |

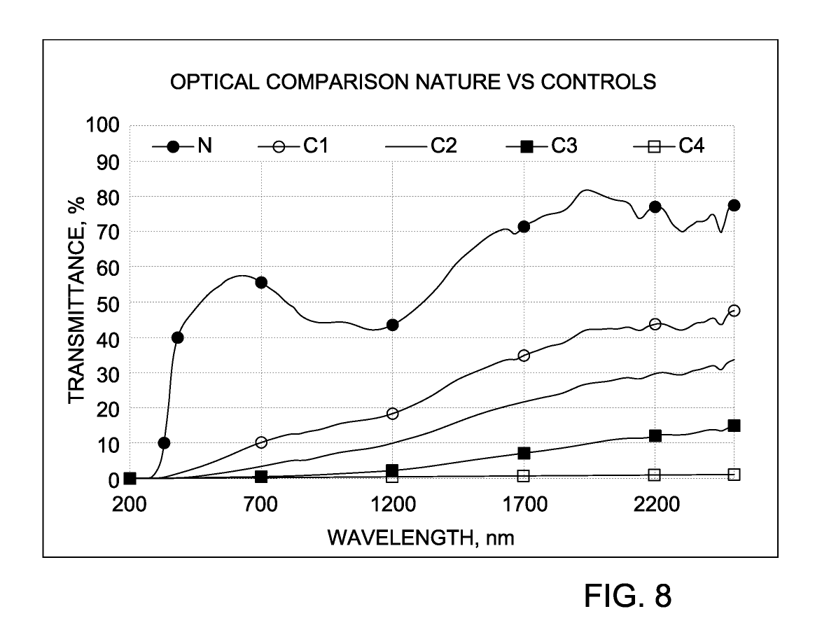

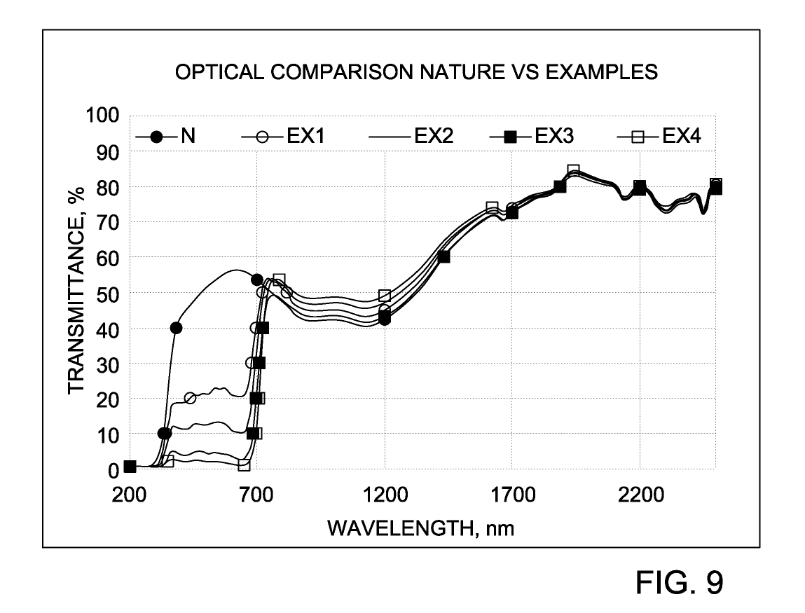

Comparisons of optical properties are presented in FIG. 8 and FIG. 9. As shown in FIG. 8, the addition of carbon black (C1, C2, C3, C4) immediately suppressed the transmittance of nature color formulation (N). The samples exhibited a continuous transmittance curve from 200 nm to 2500 nm with less than 50% transmittance. It was observed that the higher the carbon black loading, the lower the transmittance value is.

As shown in FIG. 9, the addition of photopermeable colorants (EX1, EX2, EX3, EX4) suppressed the transmittance of nature color formulation (N) at below 700 nm, but maintained the transmittance of nature color formulation at above 700 nm. The lowered transmittance at below 700 nm leads to the dark or black color of the sample at the visible range (400 nm-700 nm). The remained transmittance at above 700 nm leads to the infrared transparency of the formulation. Overall, the formulations containing photopermeable colorant showed a discontinuous change in the transmittance curve before and after 700 nm. For example, the formulation had less than 20% transmittance at below 700 nm, and greater than 40% transmittance at wavelengths above 700 nm.

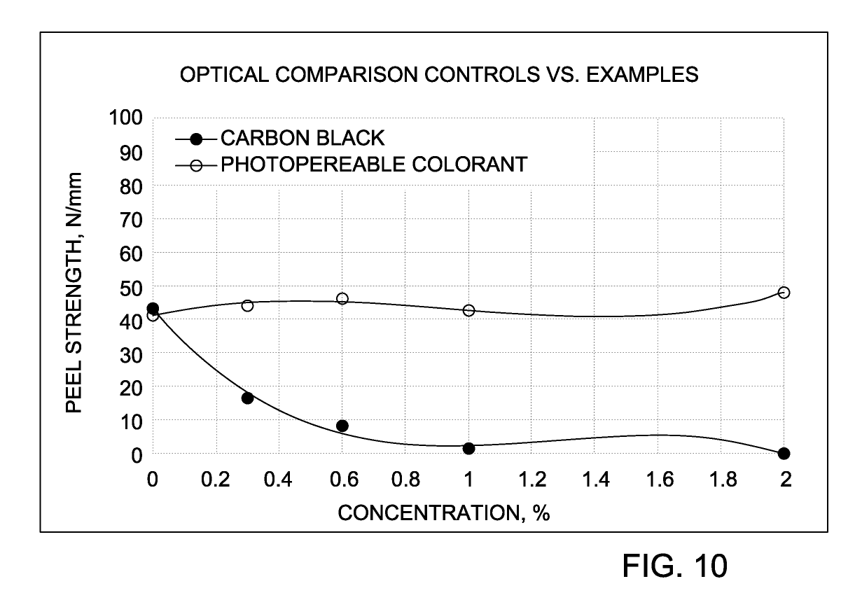

The transmittance values at 1064 nm, i.e., the LDS laser wavelength, were further compared in FIG. 10. The increased loading of carbon black appeared to decrease the transmittance. The addition of photopermeable colorant, or an increased loading of photopermeable colorant, showed no significant change in transmittance at 1064 nm of the nature (N) formulation.

The bonding strength of the formulations was tested through peel strength test. The peel strength test was performed according to an internal method on a Universal Tester, CMT4504. The testing instrument had the following specifications: maximum tensile space 570 millimeter (mm), maximum width 540 mm, maximum test force 30 kiloNewton (KN) and sensor 5 kilogram (kg), 10 kg, 50 kg, 100 kg. The test was performed in three procedures: peeling the metal plating from the substrate at starting position, laying the substrate on the platform and fix planting in proper position by the fixture, peeling strength analyzed by the computer. During testing, parameters were set as: sensor 10 kg, distance 25 mm, sample length 70 mm, sample width 3 mm. Once the peel force was obtained by computer, the peel strength was calculated according to FIG. 1.

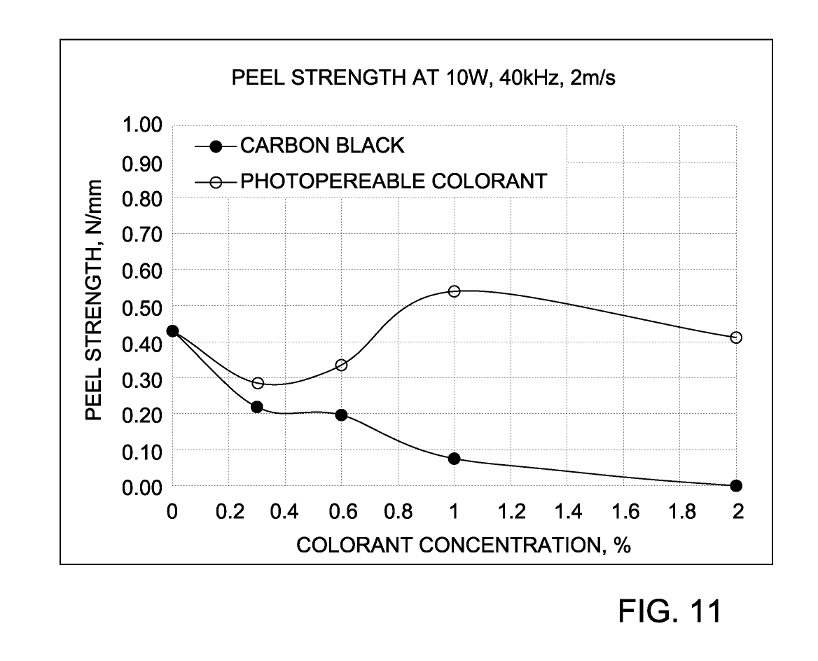

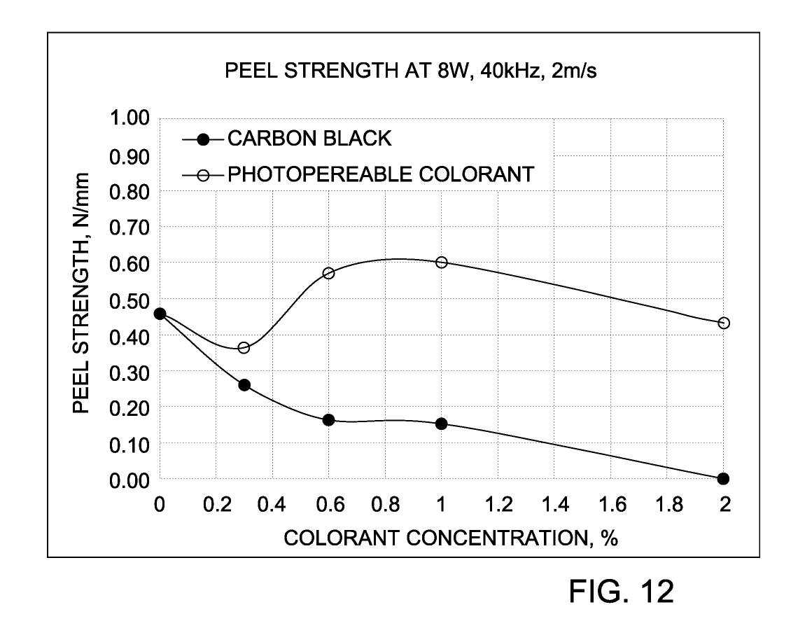

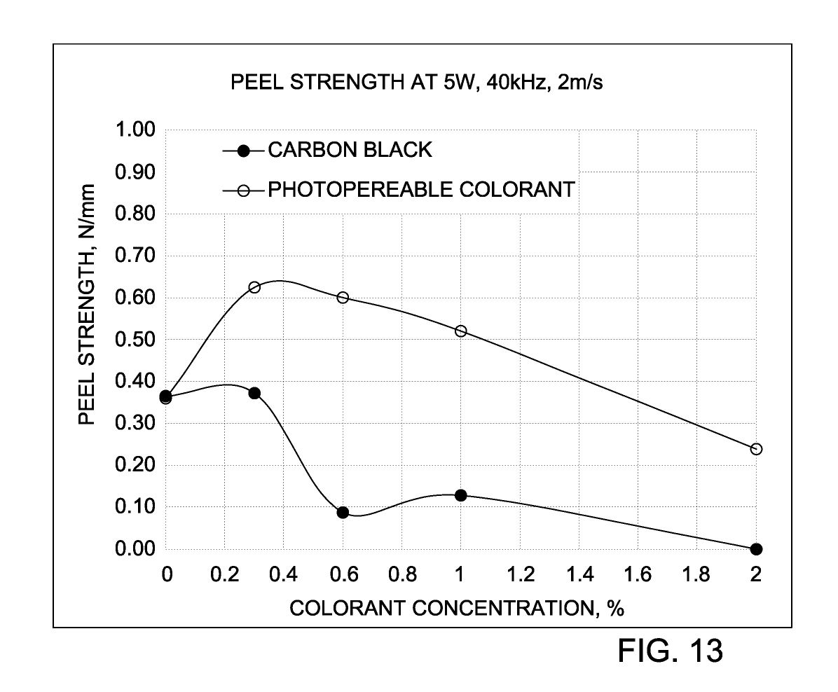

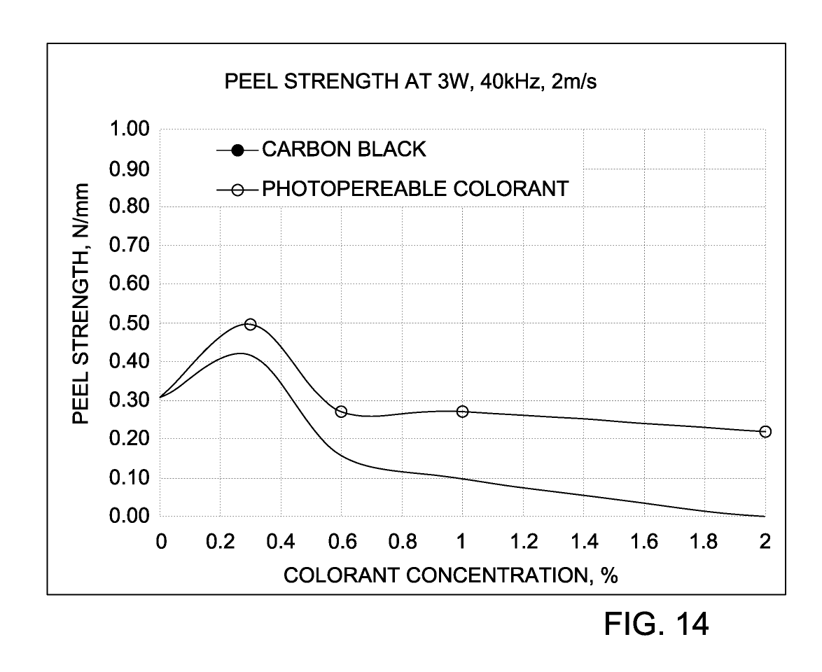

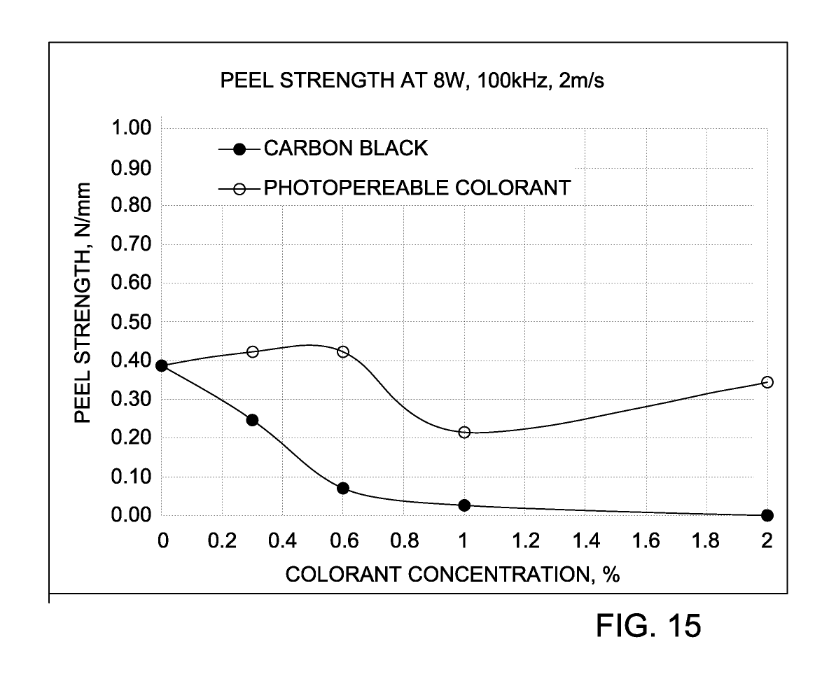

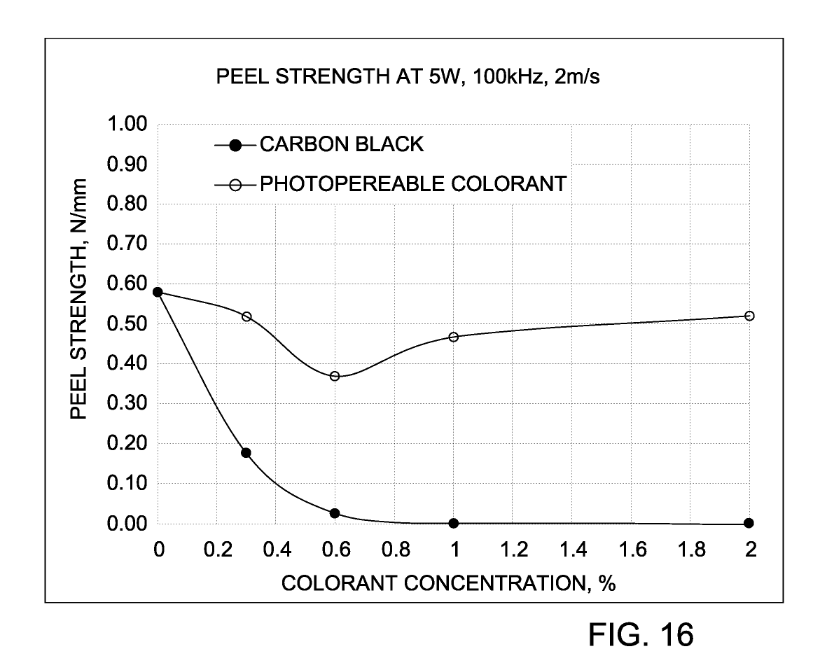

The peel strength (provided in Newtons per millimeter, N/mm) at typical laser conditions are listed in Table 11 and Table 12 and compared in FIGS. 11, 12, 13, 14, 15, and 16. At all laser conditions, the formulations containing the photopermeable colorant had a greater peel strength than those formulations containing carbon black. The increased loading of carbon black generally lower the peel strength.

TABLE 11
Peel strength of formulations containing
different loadings of carbon black

| Carbon black concentration, % | 0 | 0.3 | 0.6 | 1 | 2 |
|---|---|---|---|---|---|
| Peel strength, N/mm (10 W 40 kHz | 0.42 | 0.21 | 0.19 | 0.07 | 0.00 |
| 2 m/s) | | | | | |
| Peel strength, N/mm (8 W 40 kHz | 0.46 | 0.26 | 0.16 | 0.15 | 0.00 |
| 2 m/s) | | | | | |
| Peel strength, N/mm (5 W 40 kHz | 0.36 | 0.37 | 0.09 | 0.13 | 0.00 |
| 2 m/s) | | | | | |
| Peel strength, N/mm (3 W 40 kHz | 0.31 | 0.42 | 0.16 | 0.10 | 0.00 |
| 2 m/s) | | | | | |
| Peel strength, N/mm (8 W 100 kHz | 0.39 | 0.25 | 0.07 | 0.03 | 0.00 |
| 2 m/s) | | | | | |
| Peel strength, N/mm (5 W 100 kHz | 0.58 | 0.18 | 0.03 | 0.00 | 0.00 |
| 2 m/s) | | | | | |

TABLE 12
Peel strength of formulations containing different
loadings of photopermeable colorant

| | Photopermeable | | | | |
|---|---|---|---|---|---|
| | colorant concentration, % | | | | |
| | 0 | 0.3 | 0.6 | 1 | 2 |
| Peel strength, N/mm (10 W 40 kHz | 0.42 | 0.28 | 0.33 | 0.53 | 0.40 |
| 2 m/s) | | | | | |
| Peel strength, N/mm (8 W 40 kHz | 0.46 | 0.36 | 0.57 | 0.60 | 0.43 |
| 2 m/s) | | | | | |
| Peel strength, N/mm (5 W 40 kHz | 0.36 | 0.62 | 0.60 | 0.52 | 0.24 |
| 2 m/s) | | | | | |
| Peel strength, N/mm (3 W 40 kHz | 0.31 | 0.50 | 0.27 | 0.27 | 0.22 |
| 2 m/s) | | | | | |
| Peel strength, N/mm (8 W 100 kHz | 0.39 | 0.42 | 0.42 | 0.22 | 0.34 |
| 2 m/s) | | | | | |
| Peel strength, N/mm (5 W 100 kHz | 0.58 | 0.52 | 0.37 | 0.47 | 0.52 |
| 2 m/s) | | | | | |

As used in the specification and the appended claims, the singular forms “a,” “an” and “the” include plural referents unless the context clearly dictates otherwise. Thus, for example, reference to “a monomer” can include mixtures of two or more such monomers. Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. A value modified by a term or terms, such as “about” and “substantially,” is intended to include the degree of error associated with measurement of the particular quantity based upon the equipment available at the time of filing this application. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed. In a further example, the expression “from about 2 to about 4” also discloses the range “from 2 to 4.” The term “about” can refer to plus or minus 10% of the indicated number. Moreover, “about 10%” can indicate a range of 9% to 11%, and “about 1” may mean from 0.9-1.1. Other meanings of “about” can be apparent from the context, such as rounding off, so, for example “about 1” may also mean from 0.5 to 1.4.

As used herein, the terms “optional” or “optionally” mean that the subsequently described event, condition, component, or circumstance may or may not occur, and that the description includes instances where said event or circumstance occurs and instances where it does not.

As used herein, a “substantially similar composition” may refer to a composition comprising the polymer base resin, reinforcing filler, and laser direct structuring additive but in the absence of a photopermeable colorant. In an example, a substantially similar composition may include a polymer base resin, reinforcing filler, laser direct structuring additive, and a non-photopermeable colorant. As a further example, a substantially similar composition may comprise a polymer base resin, reinforcing filler, laser direct structuring additive, and carbon black.

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

Disclosed are component materials to be used to prepare disclosed compositions as well as the compositions themselves to be used within methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

References in the specification and concluding claims to parts by weight, of a particular element or component in a composition or article denotes the weight relationship between the element or component and any other elements or components in the composition or article for which a part by weight is expressed. Thus, in a composition containing 2 parts by weight of component X and 5 parts by weight component Y, X and Y are present at a weight ratio of 2:5, and are present in such ratio regardless of whether additional components are contained in the compound.

A weight percent of a component, unless specifically stated to the contrary, is based on the total weight of the formulation or composition in which the component is included.

Compounds disclosed herein are described using standard nomenclature. For example, any position not substituted by any indicated group is understood to have its valency filled by a bond as indicated, or a hydrogen atom. A dash (“-”) that is not between two letters or symbols is used to indicate a point of attachment for a substituent. For example, —CHO is attached through carbon of the carbonyl group. Unless defined otherwise, technical and scientific terms used herein have the same meaning as is commonly understood by one of skill in the art to which this disclosure belongs.

As used herein, the terms “number average molecular weight” or “Mn” can be used interchangeably, and refer to the statistical average molecular weight of all the polymer chains in the sample and is defined by the formula:

$$Mn = \frac{\sum {N}_{i} {M}_{i}}{\sum {N}_{i}} ,$$

where Mᵢ is the molecular weight of a chain and Nᵢ is the number of chains of that molecular weight. Mn can be determined for polymers, such as polystyrene or styrene-acrylonitrile or alpha-methylstyrene-acrylonitrile copolymers, by methods well known to a person having ordinary skill in the art.

As used herein, the terms “weight average molecular weight” or “Mw” can be used interchangeably, and are defined by the formula:

$$Mw = \frac{\sum {N}_{i} {M}_{i}^{2}}{\sum {N}_{i} {M}_{i}} ,$$

where Mi is the molecular weight of a chain and Ni is the number of chains of that molecular weight. Compared to Mn, Mw takes into account the molecular weight of a given chain in determining contributions to the molecular weight average. Thus, the greater the molecular weight of a given chain, the more the chain contributes to the Mw. It is to be understood that as used herein, Mw can be measured by gel permeation chromatography. In some cases, Mw can be measured by gel permeation chromatography and calibrated with known standards, such as, for example polystyrene standards or polycarbonate standards. As an example, a polycarbonate of the present disclosure can have a weight average molecular weight of greater than 5,000 Daltons, or greater than about 5,000 Daltons based on polystyrene (PS) standards. As a further example, the polycarbonate can have an Mw of from 20,000 Daltons to 100,000 Daltons, or from about 20,000 to about 100,000 Daltons.

1. A composition comprising:
from 10 wt. % to 90 wt. % of a polymer base resin;
from 0.1 wt. % to 60 wt. % of a reinforcing filler;
from 0.1 wt. % to 10 wt. % of a laser direct structuring additive; and
from 0.01 wt. % to 10 wt. % of a photopermeable colorant, wherein
the combined weight percent value of all components does not exceed 100 wt. %, and
all weight percent values are based on the total weight of the composition,
the composition exhibits a transmittance of up to 20% at from 190 nm to 400 nm and a transmittance of greater than 50% at from 700 nm to 2500 nm, and
the composition is configured to be activated by laser.

2. A composition comprising:
from 10 wt. % to 90 wt. % of a polymer base resin;
from 0.1 wt. % to 60 wt. % of a reinforcing filler;
from 0.1 wt. % to 10 wt. % of a laser direct structuring additive; and
from 0.01 wt. % to 10 wt. % of a photopermeable colorant, wherein
the combined weight percent value of all components does not exceed 100 wt. %, and
all weight percent values are based on the total weight of the composition,
the composition exhibits a change in transmittance of at least 20% between a transmittance observed between 190 nm and 400 nm and a transmittance observed from 700 nm to 2500 nm, and
the composition is configured to be activated by laser.

3. The composition of claim 1, wherein the laser activated composition is configured to be metal plated.

4. The composition of claim 3, wherein the metal plated composition exhibits an average Plating Index at less than 10% difference from a Plating Index of a substantially similar metal plated composition in the absence of a photopermeable colorant when measured at the same laser intensities.

5. The composition of claim 1, wherein the composition is activated by laser at 1064 nm.

6. The composition of claim 1, wherein an amount of the photopermeable colorant is configured such that the composition has a transmittance of below 20% at from 190 nm to 400 nm.

7. The composition of claim 1, wherein the loading of the photopermeable colorant is configured such that the composition has a transmittance of below 20% at from 190 nm to 400 nm and wherein the composition is subjected to laser irradiation at wavelengths of from 700 nm to 2500 nm without exhibiting damage to an irradiated surface of the composition when compared to a substantially similar composition excluding the photopermeable colorant but comprising a non-photopermeable colorants instead of photopermeable colorants under comparable laser irradiation intensity and frequencies.

8. The composition of claim 1, wherein the polymer base resin comprises polypropylene, polyethylene, ethylene based copolymer, polycarbonate, polyamide, polyester, polyoxymethylene, polybutylene terephthalate, polyethylene terephthalate, polycyclohexylendimethylene terephthalate, liquid crystal polymers, polyphenylene Sulfide, polyphenylene ether, polyphenylene oxide-polystyrene blends, polystyrene, high impact modified polystyrene, acrylonitrile-butadiene-styrene terpolymer, acrylic polymer, polyetherimide, polyurethane, polyetheretherketone, poly ether sulphone, or a combination thereof.

9. The composition of claim 1, wherein the polymer base resin comprises a polycarbonate having units derived from bisphenol A or a poly(aliphatic ester)-polycarbonate copolymer, or a combination thereof.

10. The composition of claim 1, wherein the reinforcing filler comprises glass fiber, carbon fiber, a mineral filler, or a combination thereof.

11. The composition of claim 10, wherein the reinforcing filler comprises flat glass fiber.

12. The composition of claim 1, wherein the laser direct structuring additive comprises a heavy metal mixture oxide spinel, such as copper chromium oxide spinel; a copper salt, such as copper hydroxide phosphate copper phosphate, copper sulfate, cuprous thiocyanate, spinel based metal oxides (such as copper chromium oxide), organic metal complexes (such as palladium/palladium-containing heavy metal complexes), metal oxides, metal oxide-coated fillers, antimony doped tin oxide coated on a mica substrate, a copper containing metal oxide, a zinc containing metal oxide, a tin containing metal oxide, a magnesium containing metal oxide, an aluminum containing metal oxide, a gold containing metal oxide, a silver containing metal oxide, or the like; or a combination including at least one of the foregoing LDS additives.

13. The composition of claim 1, wherein the photopermeable colorant comprises solvent red, solvent blue, solvent green, or disperse yellow, or some combination thereof.

14. The composition of claim 1, wherein the photopermeable colorant does not absorb light at wavelengths longer than 600 nm.

15. The composition of claim 1, wherein the photopermeable colorant does not absorb light at wavelengths longer than 700 nm.

16. The composition of claim 1, further comprising an additive.

17. The composition of claim 16, wherein the additive comprises ultraviolet agents, ultraviolet stabilizers, heat stabilizers, antistatic agents, anti-microbial agents, impact modifiers, anti-drip agents, radiation stabilizers, pigments, dyes, fibers, fillers, plasticizers, fibers, flame retardants, antioxidants, lubricants, wood, glass, and metals, and combinations thereof.

18. The composition of claim 16, wherein the additive comprises an acrylic impact modifier comprising an ethylene-ethylacrylate copolymer.

19. A molded article formed according to the composition of claim 1.

20. A method of forming a composition comprising:
from about 10 wt. % to about 90 wt. % of a polymer base resin;
from about 0.1 wt. % to about 60 wt. % of a reinforcing filler;
from about 0.1 wt. % to about 10 wt. % of a laser direct structuring additive; and
from about 0.01 wt. % to about 10 wt. % of a photopermeable colorant, wherein
the combined weight percent value of all components does not exceed about 100 wt. %,
all weight percent values are based on the total weight of the composition,
the composition exhibits a percent transmittance of up to about 20% at from about 190 nm to about 400 nm and a percent transmittance of greater than 50% at from about 700 nm to about 2500 nm,
the composition is configured to be metal plated, and
the metal plated composition exhibits an average Plating Index at less than 10% difference from a Plating Index of a substantially similar metal plated composition in the absence of a photopermeable colorant when measured at the same laser intensities.
